(19) United States
(12) Patent Application Publication
(10) Pub. No.: US 2025/0391762 A1
(43) Pub. Date: Dec. 25, 2025

(54) BRANCHED HYBRID FLEX STRUCTURES

(71) Applicant: ADEIA SEMICONDUCTOR BONDING TECHNOLOGIES INC., San Jose, CA (US)

(72) Inventors: Cyprian Emeka Uzoh, San Jose, CA (US); Rajesh Katkar, San Jose, CA (US)

(21) Appl. No.: 18/991,156

(22) Filed: Dec. 20, 2024

Related U.S. Application Data
(60) Provisional application No. 63/662,994, filed on Jun. 21, 2024.

(51) Int. Cl. H01L 23/498; H01L 23/00; H01L 23/13; H01L 23/14

(52) U.S. Cl. CPC H01L 23/4985; H01L 23/13; H01L 23/145; H01L 24/08; H01L 2224/08225

(57) ABSTRACT

Methods for fabricating branched substrates having conductive contact pads and hybrid dielectric bonding surfaces for directly bonding dies and electrically connecting them to the contact pads. A branched substrate can include a main portion and one or more branch portions hybrid bonded to the main portion. Some sections of the branched substrate can be flexible to allow deformable electrical connection between components that are hybrid bonded to different regions of the branched substrate. A flexible branch portion may provide electrical connection between vertically separated layers of two components. The method includes directly bonding a branch portion of the branched substrate to the main portion of the branched substrate via a hybrid bonding interface comprising a conductive interface between contact pads of the main and branch portions and a hybrid bonded dielectric interface between dielectric surfaces of the of the main and branch portions.

### CROSS-REFERENCE TO RELATED APPLICATIONS

This application claims priority to U.S. Provisional Patent Application No. 63/662,994, filed on Jun. 21, 2024, the entire contents of which are incorporated by reference herein in their entirety and for all purposes.

### BACKGROUND

### Field

The field relates to structures having hybrid bonding surfaces including dielectric and conductive regions and methods for forming the same.

### Description of the Related Art

Semiconductor elements, such as integrated device dies or chips, may be mounted or stacked on other elements. For example, a semiconductor element can be stacked on top of another semiconductor element and the bonded elements can electrically communicate with one another through contact pads included in the hybrid bonding surfaces. For example, hybrid bonding surfaces of a first and second integrated device dies can be bonded on to hybrid bonding surfaces of a semiconductor substrate and the first and second integrated device dies can electrically communicate via contact pads of the respective hybrid binding surfaces. It can be challenging to integrate semiconductor elements of different types or material sets, on a substrate or in a package due to, for example, mismatches in coefficient of thermal expansion (CTE). Further, it can be challenging to provide communication between stacks of semiconductor elements and to maintain a low profile for the package or device.

### BRIEF DESCRIPTION OF THE DRAWINGS

The detailed description is set forth with reference to the accompanying figures. The use of the same numbers in different figures indicates similar or identical items. For this discussion, the devices and systems illustrated in the figures are shown as having a multiplicity of components. Various implementations of devices and/or systems, as described herein, may include fewer components and remain within the scope of the disclosure. Alternatively, other implementations of devices and/or systems may include additional components, or various combinations of the described components, and remain within the scope of the disclosure.

FIG. 1A schematically illustrates an example flexible bonded structure including a flexible hybrid bonding layer and a hybrid bonding surface with two separate regions for direct bonding two different elements and providing an electrical connection between them.

FIG. 1B schematically illustrates a double-sided flexible hybrid bonding substrate (or layer) including a flexible hybrid layer and two hybrid bonding surfaces formed on opposite sides of the double-sided flexible hybrid bonding substrate with separate regions for direct bonding of different elements to opposite sides of the double-sided flexible and providing an electrical connection between them.

FIG. 2A schematically illustrates an example flexible hybrid bonding substrate depicting a cross-sectional side view (top panel), and a top view (bottom panel) of the flexible hybrid bonding substrate.

FIGS. 2B-2C schematically illustrates top views of example flexible bonded structures comprising the flexible hybrid bonding substrate shown in FIG. 2A and a plurality of (e.g., five and three) components (e.g., dies) hybrid bonded to different hybrid bonding surface regions thereon.

FIG. 3A schematically illustrates top view (left) and side cross-sectional view (right) of the main portion and branch portion of a branched flexible hybrid bonding substrate before formation of the branched flexible hybrid bonding substrate.

FIG. 3B schematically illustrates a top view (left) and a side cross-sectional view (right) of a branched flexible hybrid bonding substrate formed by directly bonding the main portion and the branch portion shown in FIG. 3A.

FIG. 3C schematically illustrates a top view of a branched bonded structure comprising the branched flexible hybrid bonding substrate shown in FIG. 3B and four components (e.g., dies) hybrid bonded to the three hybrid bonding regions of the branched flexible hybrid bonding substrate.

FIG. 3D schematically illustrates a top view of a branched bonded structure comprising a branched flexible hybrid bonding substrate and six components hybrid bonded to seven hybrid bonding regions of the branched flexible hybrid bonding substrate.

FIG. 3E schematically illustrates a top view of a branched bonded structure comprising a branched flexible hybrid bonding substrate and three components hybrid bonded to three hybrid bonding regions of the branched flexible hybrid bonding substrate.

FIG. 4A schematically illustrates a top view of an example branched bonded structure comprising a branched flexible hybrid bonding substrate having a main portion 402a and three separate branch portions extending away from the main portion, where two branch portions are bonded (e.g., hybrid bonded) to two multilayer stacks.

FIG. 4B schematically illustrates a cross-sectional side view of a multilayer bonded structure bonded to the branched flexible bonded structure shown in FIG. 4A across a first branch portion.

FIG. 4C schematically illustrates a cross-sectional side view of another multilayer bonded structure bonded to the branched flexible bonded structure shown in FIG. 4A across a third branch portion.

FIG. 5A schematically illustrates a side cross-sectional view of a branched flexible bonded structure formed by directly bonding two flexible hybrid bonding substrates, each having a hybrid bonding surface, where one component is hybrid bonded to the hybrid bonding surface of each of the flexible hybrid bonding substrates.

FIG. 5B schematically illustrates a side cross-sectional view of a branched flexible bonded structure formed by directly bonding a double-sided flexible hybrid bonding substrate to a single-sided flexible hybrid bonding substrate, where one component is hybrid bonded to the single-sided flexible hybrid bonding substrate and two components are bonded on the opposing hybrid bonding surfaces of the double-sided flexible hybrid bonding substrate.

FIG. 5C schematically illustrates a side cross-sectional view of a branched flexible bonded structure across a branch portion of the corresponding branched flexible hybrid bonding substrate, the branch portion having a hybrid bonding surface opposing a hybrid bonding surface of the main portion. One component is hybrid bonded on the top surface of the main portion and one component it is hybrid bonded to the bottom surface of the branch portion.

FIG. 6A-6E schematically illustrate selected steps of an example process for fabricating a branched flexible hybrid bonding substrate.

FIG. 7A-7E schematically illustrate selected steps of an example process for fabricating a branched flexible bonded structure comprising a branched flexible hybrid bonding substrate.

FIGS. 8A-8B schematically illustrate cross-sectional side views of two elements (A) prior to hybrid bonding and (B) after hybrid bonding.

### DETAILED DESCRIPTION

There is a growing demand for directly bonding semiconductor elements having contact pads arranged at a fine pitch, so as to increase interconnect density and provide improved electrical capabilities. Direct hybrid bonds may be formed by fabricating semiconductor elements (e.g., wafers or dies) having polished bonding surfaces including a nonconductive field region and one or more conductive features (e.g., conductive contact pads) at least partially embedded in the nonconductive field region. The nonconductive field regions of two semiconductor elements can be hybrid bonded at low temperature without using an adhesive to form a bonded structure (e.g., via covalently bonded dielectric-to-dielectric surfaces). The hybrid bonded structure can be heated to cause expansion of the conductive contact pads therein so as to form a bond between opposing surfaces of the conductive contact pads and thereby provide electrical connection between the conductive contact pads. Accordingly, a hybrid bonding surface comprises nonconductive (e.g., dielectric) and conductive regions formed on a nonconductive (e.g., insulating) layer. In some embodiments, the nonconductive region of the hybrid bonding surface may comprise a inorganic dielectric material. In some cases, the nonconductive (e.g., dielectric or field regions) may be activated for direct bonding. A hybrid bonding interface (also referred to as hybrid bonded region) comprises a boundary of two hybrid bonding surfaces providing electrical connection between at least two opposing contact pads. A hybrid bonding (or substrate) layer may comprise a layer (or substrate) having at least one hybrid bonding surface configured to be hybrid bonded to a hybrid bonding surface of another element (e.g., a component, die, structure, substrate, or the like). In some cases, a hybrid surface may comprise nonconductive (e.g., dielectric) and conductive regions where the nonconductive regions are not activated for direct bonding. In some examples, a dielectric region of a hybrid surface may be activated by adding suitable species (e.g., nitrogen species) to transform hybrid surface to a hybrid bonding surface.

In various implementations, a substrate (e.g., a hybrid bonding substrate) may comprise an insulating material with embedded conductive traces and contact features. The substrate can be devoid of active circuitry and passive circuitry, such that the substrate's only function is to route signals along the conductors. But in other embodiments, the substrate can include embedded passive devices. The substrates illustrated herein are flexible substrates (e.g., they may comprise an organic layer), but in other embodiments, the substrate can comprise other types of substrates, such as a printed circuit board (PCB), a ceramic substrate, and the like.

In some cases, a portion of a hybrid bonding substrate or layer may be displaced with respect to another portion of the same substrate or layer, e.g., by a mechanical force or due to thermal expansion. For example, heat generated by a first component hybrid bonded to a first portion of a hybrid bonding substrate may cause that portion to be expanded and move with respect to another portion of the hybrid bonding substrate that is hybrid bonded to a second component. As another example, a first portion of a hybrid bonding substrate or layer may be used to provide electrical connection between a first component and a second component vertically displaced with respect to the first component. Various hybrid layers and substrates disclosed herein may include a flexible region, flexible portion, or flexible layer that allows two different portions or sections a hybrid layer or structure to be displaced by different amounts without causing mechanical damage in the substrate or layer or electrical disconnection between different sections of the substrate or layer. For example, some of the disclosed methods may be used to fabricate a flexible hybrid layer or flexible hybrid bonding substrate comprising one or more contact pads and/or conductive lines partially embedded in a flexible (or deformable) layer having at least one hybrid bonding surface. In various implementations, a flexible layer may comprise compliant material comprising organic material such as a polymer, e.g., a liquid crystal polymer (LCP) and/or a polyimide (PYRALIN® PI 2611) or polyamide-imide Torlon® or silicone rubber or benzocyclobutene (BCB) for example. In some cases, a flexible layer may comprise one or more compliant materials. For a examples, a mixture or combination of different types of polymers. In some, cases, a flexible layer may comprise 5-10 weight %, 10-20 weight %, 20-40 weight %, 40-50 weight %, 50-60 weight %, 60-70 weight %, 70-80 weight %, 80-90 weight %, or 90-100 weight %, polymer or another compliant material. In some cases, a flexible layer or substrate, may comprise a deformable region or a deformable layer comprising a compliant material. In some cases, a complaint material may have a Young's modulus from 0.05 GPa to 5 GPa, 5 GPa to 10 Gpa, 10 to 45 Gpa, 45 to 50 Gpa or any ranges formed by these values or larger or smaller values. In some embodiments, the compliant material selected to have a Young's modulus that allows the corresponding flexible substrate (having a deformable region comprising the compliant material) to be deformed more than or equal to a minimum desired deformation. In some examples, the minimum desired deformation may comprise a radius of curvature of a bent flexible substrate to be less than 100 times, less than 50 times, or less than 20 times the thickness of the flexible substrate without disrupting an electrical connection within the substrate. As such, in some cases, the compliant material selected based at least in part on a thickness of the substrate (e.g., along a direction normal to a main surface of the substrate). For example, when a thickness of the deformable region, along a direction normal to a main surface of the substrate, is larger than 5 microns, the compliant material (the deformable region of the substrate) may be selected to have Young's modulus less than 40 GPa.

In some examples, a flexible hybrid layer or substrate may be configured to allow two hybrid surface regions spaced apart by a distance equal to the thickness of the layer or substrate, to be displaced with respect to each other by more than the 20%, 50%, 100%, 200%, 300%, 400%, 500% of the thickness without suffering mechanical damage, and/or disrupting electrical connectivity (e.g., between the two hybrid surface regions (e.g., due to disconnection of an electrical link at least partially embedded in the layer or substrate). In some examples, a flexible layer or a compliant portion of a flexible layer (e.g., a polymer layer) may have a coefficient of thermal expansion (CTE) greater than 15 ppm/° C. and less than 60 ppm/° C. In some examples, a flexible layer or a compliant portion of a flexible layer (e.g., a polymer layer) may have a CTE of less than 15 ppm/° C., from 15 to 20 ppm/° C., from 20 to 30 ppm/° C., from 30-40 ppm/° C., from 40 to 50 ppm/° C., from 50 to 60 ppm/° C. In some examples, a flexible layer or substrate may comprise a composite material. In some such examples, the composite material can be an inorganic material, an organic material, or a combination thereof. In some such examples, the composite material may comprise particulate reinforcement in the form or fibers (e.g., chopped fibers), particles, or particles having any shapes. In some cases, the particulate reinforcement can be less than 10%, 20%, or 30% of the volume of the material. In some cases, the composite material may include less than 10, 20, or 30 weight % of the reinforcing particulates. In some cases, particulate reinforcement may comprise inorganic or organic particles or fibers, for example a polyimide or silicone polymer containing milled para-aramid (Kelvar®) reinforcing particulates. In some embodiments, a flexible layer may comprise a flexible region that allows two regions or sections of the flexible layer on the opposite sides of the flexible region to be displaced relative to each other by an amount larger than X% of the thickness of the flexible layer without being damaged and/or without disrupting an electrical connection via the flexible region. In some cases, X can be larger than 20%, larger than 70%, larger than 90%, larger than 100%, larger than 150% or larger values. In some cases, such flexible region may comprise one or more conductive lines electrically connecting conductive portion of the two regions or sections. In some cases, the relative displacement between the two regions or sections can be along a direction parallel to a main surface of the flexible layer, or perpendicular to a main surface of the flexible layer.

In some embodiments, a sublayer, a layer, or region of a substrate or structure may be considered to be flexible even though the layer or structure is rendered inflexible due to presence of other layers or a surrounding material, such as a molding compound.

### Examples of Direct Bonding Methods and Hybrid bonded Structures

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 808a and/or 808b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to plasma, explained below).

The hybrid bonding interface (also referred to as hybrid bonded region) between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the hybrid bonding interface between non-conductive bonding surfaces. In some embodiments, the hybrid bonding interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

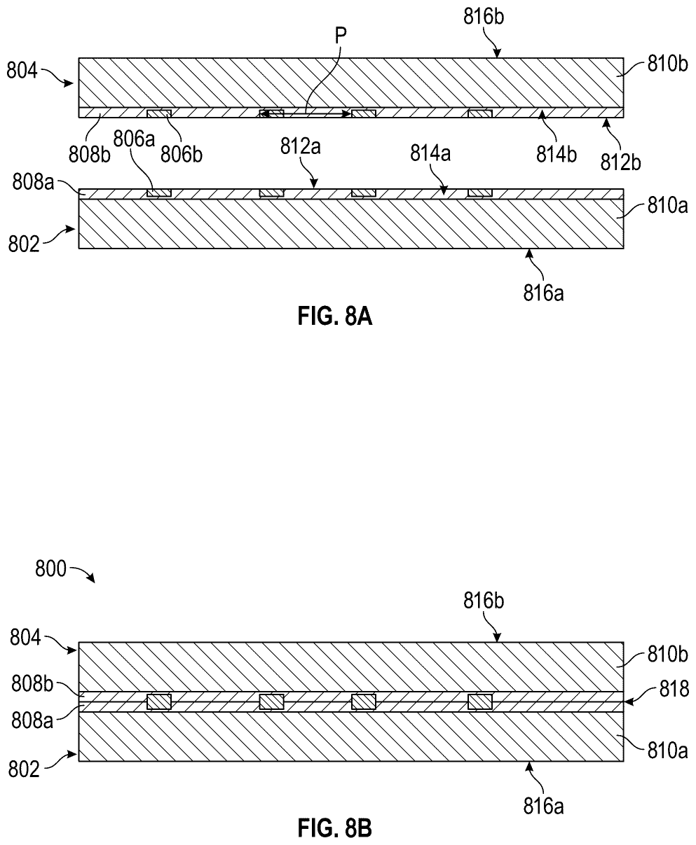

FIGS. 8A and 8B schematically illustrate cross-sectional side views of first and second elements 802, 804 prior to and after, respectively, a process for forming a directly bonded structure, and more particularly a hybrid bonded structure, according to some embodiments. In FIG. 8B, a bonded structure 800 comprises the first and second elements 802 and 804 that are directly bonded to one another at a hybrid bonding interface (or hybrid bonded region) 818 without an intervening adhesive. Conductive features 806a of a first element 802 may be electrically connected to corresponding conductive features 806b of a second element 804. In the illustrated hybrid bonded structure 800, the conductive features 806a are directly bonded to the corresponding conductive features 806b without intervening solder or conductive adhesive.

The conductive features 806a and 806b of the illustrated embodiment are embedded in, and can be considered part of, a first bonding layer 808a of the first element 802 and a second bonding layer 808b of the second element 804, respectively. Field regions of the bonding layers 808a, 808b extend between and partially or fully surround the conductive features 806a, 806b. The bonding layers 808a, 808b can comprise layers of non-conductive materials suitable for direct bonding, as described above, and the field regions are directly bonded to one another without an adhesive. The non-conductive bonding layers 808a, 808b can be disposed on respective front sides 814b, 814b of base substrate portions 810a, 810b.

The first and second elements 802, 804 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 802, 804, and back-end-of-line (BEOL) interconnect layers over such semiconductor portions. The bonding layers 808a, 808b can be provided as part of such BEOL layers (conductive layer damascene process or non-damascene coating of conductive layer) during device fabrication, as part of redistribution layers (RDL), or as specific bonding layers added to existing devices, with bond pads extending from underlying contacts. Active devices and/or circuitry can be patterned and/or otherwise disposed in or on the base substrate portions 810a, 810b, and can electrically communicate with at least some of the conductive features 806a, 806b. Active devices and/or circuitry can be disposed at or near the front sides 814b, 814b of the base substrate portions 810a, 810b, and/or at or near opposite backsides 816a, 816b of the base substrate portions 810a, 810b. In other embodiments, the base substrate portions 810a, 810b may not include active circuitry, but may instead comprise dummy substrates, passive interposers, passive optical elements (e.g., glass substrates, gratings, lenses), etc. The bonding layers 808a, 808b are shown as being provided on the front sides of the elements, but similar bonding layers can be additionally or alternatively provided on the back sides of the elements.

In some embodiments, the base substrate portions 810a, 810b can have significantly different coefficients of thermal expansion (CTEs), and bonding elements that include such different based substrate portions can form a heterogenous bonded structure. The CTE difference between the base substrate portions 810a and 810b, and particularly between bulk semiconductor (typically single crystal) portions of the base substrate portions 810a, 810b, can be greater than 5 ppm/° C. or greater than 10 ppm/° C. For example, the CTE difference between the base substrate portions 810a and 810b can be in a range of 5 ppm/° C. to 1700 ppm/° C., 5 ppm/° C. to 40 ppm/° C., 10 ppm/° C. to 1700 ppm/° C., or 10 ppm/° C. to 40 ppm/° C.

In some embodiments, one of the base substrate portions 810a, 810b can comprise optoelectronic single crystal materials, including perovskite materials, that are useful for optical piezoelectric or pyroelectric applications, and the other of the base substrate portions 810a, 810b comprises a more conventional substrate material. For example, one of the base substrate portions 810a, 810b comprises lithium tantalate (LiTaO3) or lithium niobate (LiNbO3), and the other one of the base substrate portions 810a, 810b comprises silicon (Si), quartz, fused silica glass, sapphire, or a glass. In other embodiments, one of the base substrate portions 810a, 810b comprises a III-V single semiconductor material, such as gallium arsenide (GaAs) or gallium nitride (GaN), and the other one of the base substrate portions 810a, 810b can comprise a non-III-V semiconductor material, such as silicon (Si), or can comprise other materials with similar CTE, such as quartz, fused silica glass, sapphire, or a glass. In still other embodiments, one of the base substrate portions 810a, 810b comprises a semiconductor material and the other of the base substrate portions 810a, 810b comprises a packaging material, such as a glass, organic or ceramic substrate.

In some arrangements, the first element 802 can comprise a singulated element, such as a singulated integrated device die. In other arrangements, the first element 802 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 804 can comprise a singulated element, such as a singulated integrated device die. In other arrangements, the second element 804 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive and may include markings indicative of the common singulation process for the bonded structure (e.g., saw markings if a saw singulation process is used).

While only two elements 802, 804 are shown, any suitable number of elements can be stacked in the bonded structure 800. For example, a third element (not shown) can be stacked on the second element 804, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent to one another along the first element 802. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 808a, 808b, the bonding layers 808a, 808b can be prepared for direct bonding. Non-conductive bonding surfaces 812a, 812b at the upper or exterior surfaces of the bonding layers 808a, 808b can be prepared for direct bonding by polishing, for example, by chemical mechanical polishing (CMP). The roughness of the polished bonding surfaces 812a, 812b can be less than 30 Å rms. For example, the roughness of the bonding surfaces 812a and 812b can be in a range of about 0.1 Å rms to 15 Å rms, 0.5 Å rms to 10 Å rms, or 1 Å rms to 5 Å rms. Polishing can also be tuned to leave the conductive features 806a, 806b recessed relative to the field regions of the bonding layers 808a, 808b.

Preparation for direct bonding can also include cleaning and exposing one or both of the bonding surfaces 812a, 812b to a plasma and/or etchants to activate at least one of the surfaces 812a, 812b. In some embodiments, one or both of the surfaces 812a, 812b can be terminated with a species after activation or during activation (e.g., during the plasma and/or etch processes). Without being limited by theory, in some embodiments, the activation process can be performed to break chemical bonds at the bonding surface(s) 812a, 812b, and the termination process can provide additional chemical species at the bonding surface(s) 812a, 812b that alters the chemical bond and/or improves the bonding energy during direct bonding. In some embodiments, the activation and termination are provided in the same step, e.g., a plasma to activate and terminate the surface(s) 812a, 812b. In other embodiments, one or both of the bonding surfaces 812a, 812b can be terminated in a separate treatment to provide the additional species for direct bonding. In various embodiments, the terminating species can comprise nitrogen. For example, in some embodiments, the bonding surface(s) 812a, 812b can be exposed to a nitrogen-containing plasma. Other terminating species can be suitable for improving bonding energy, depending upon the materials of the bonding surfaces 812a, 812b. Further, in some embodiments, the bonding surface(s) 812a, 812b can be exposed to fluorine. For example, there may be one or multiple fluorine concentration peaks at or near a hybrid bonding interface 818 between the first and second elements 802, 804. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 800, the hybrid bonding interface (or hybrid bonded region) 818 between two non-conductive materials (e.g., the bonding layers 808a, 808b) can comprise a very smooth interface with higher nitrogen (or other terminating species) content and/or fluorine concentration peaks at the hybrid bonding interface 818. In some embodiments, the nitrogen and/or fluorine concentration peaks may be detected using various types of inspection techniques, such as SIMS techniques. The polished bonding surfaces 812a and 812b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 808a and 808b can be hybrid bonded to one another without an adhesive. In some embodiments, the elements 802, 804 are brought together at room temperature, without the need for application of a voltage, and without the need for application of external pressure or force beyond that used to initiate contact between the two elements 802, 804. Contact alone can cause direct bonding between the non-conductive surfaces of the bonding layers 808a, 808b (e.g., covalent dielectric bonding). Subsequent annealing of the bonded structure 800 can cause the conductive features 806a, 806b to directly bond.

In some embodiments, prior to direct bonding, the conductive features 806a, 806b are recessed relative to the surrounding field regions, such that a total gap between opposing contacts after dielectric bonding and prior to anneal is less than 15 nm, or less than 10 nm. Because the recess depths for the conductive features 806a and 806b can vary across each element, due to process variation, the noted gap can represent a maximum or an average gap between corresponding conductive features 806a, 806b of two joined elements (prior to anneal). Upon annealing, the conductive features 806a and 806b can expand and contact one another to form a metal-to-metal direct bond.

During annealing, the conductive features 806a, 806b (e.g., metallic material) can expand while the direct bonds between surrounding non-conductive materials of the bonding layers 808a, 808b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 806a, 806b can comprise discrete pads, contacts, electrodes, or traces at least partially embedded in the non-conductive field regions of the bonding layers 808a, 808b. In some embodiments, the conductive features 806a, 806b can comprise exposed contact surfaces of TSVs (e.g., through silicon vias).

As noted above, in some embodiments, in the elements 802, 804 of FIG. 8A prior to direct bonding, portions of the respective conductive features 806a and 806b can be recessed below the non-conductive bonding surfaces 812a and 812b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 806a, 806b or to average depths of the recesses relative to local non-conductive field regions. Even for an individual conductive feature 806a, 806b, the vertical recess can vary across the feature, and so can be measured at or near the lateral middle or center of the cavity in which a given conductive feature 806a, 806b is formed, or can be measured at the sides of the cavity.

Beneficially, the use of hybrid bonding techniques (such as Direct Bond Interconnect, or DBIR, techniques commercially available from Adeia of San Jose, CA) can enable high density of connections between conductive features 806a, 806b across the direct hybrid bonding interface 818 (e.g., small or fine pitches for regular arrays).

In some embodiments, a pitch p of the conductive features 806a, 806b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 806a and 806b to one of the lateral dimensions (e.g., a diameter) of the bonding pad is less than is less than 20, or less than 10, or less than 5, or less than 3 and sometimes desirably less than 2. In various embodiments, the conductive features 806a and 806b and/or traces can comprise copper or copper alloys, although other metals may be suitable, such as nickel, aluminum, or alloys thereof. The conductive features disclosed herein, such as the conductive features 806a and 806b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 802, 804, as shown, the orientations of one or more conductive features 806a, 806b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 806b in the bonding layer 808b (and/or at least one internal conductive feature, such as a BEOL feature) of the upper element 804 may be tapered or narrowed upwardly, away from the bonding surface 812b. By way of contrast, at least one conductive feature 806a in the bonding layer 808a (and/or at least one internal conductive feature, such as a BEOL feature) of the lower element 802 may be tapered or narrowed downwardly, away from the bonding surface 812a. Similarly, any bonding layers (not shown) on the backsides 816a, 816b of the elements 802, 804 may taper or narrow away from the backsides, with an opposite taper orientation relative to front side conductive features 806a, 806b of the same element.

As described above, in an anneal phase of hybrid bonding, the conductive features 806a, 806b can expand and contact one another to form a metal-to-metal direct bond. In some embodiments, the materials of the conductive features 806a, 806b of opposite elements 802, 804 can interdiffuse during the annealing process. In some embodiments, metal grains grow into each other across the hybrid bonding interface 818. In some embodiments, the metal is or includes copper, which can have grains oriented along the 111 crystal plane for improved copper diffusion across the hybrid bonding interface 818. In some embodiments, the conductive features 806a and 806b may include nanotwinned copper grain structure, which can aid in merging the conductive features during anneal. There is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b.

As described above, in some embodiments, two elements (e.g., two layers, a layer and a die, a layer and a substrate, a die and a substrate, or other combinations) can be hybrid bonded to one another without an adhesive, e.g., by low temperature dielectric-to-dielectric bonding. In some cases, each element may include a non-conductive (e.g., dielectric) field region comprising at least one non-conductive material (dielectric material). In some examples, the non-conductive material (also referred to as dielectric bonding material) can be an inorganic. In some examples, a non-conductive field region of an element is a dielectric layer (e.g., an inorganic dielectric layer). A dielectric layer of the first element can be directly bonded to a corresponding dielectric layer of the second element without an adhesive. In some embodiments, the dielectric layer of at least one element may be disposed on a flexible region or flexible layer of the element. In some cases, the flexible region or flexible layer can be deformable region of layer configured to be deformed without a damage to its morphology or a disruption in electrical connectivity therein. In some embodiments, the flexible region may be an elastically deformable material. A region of a dielectric layer that is bonded to the corresponding region of another dielectric layer can be referred to as nonconductive bonding region, dielectric bonding region, or bonding region. In some cases, the bonding region of the dielectric layer may comprise a dielectric bonding surface region. The dielectric bonding surface of a dielectric layer may be also referred to as a field area or a field region of the dielectric layer. In some cases, the nonconductive bonding region or dielectric bonding region and the top conductive surfaces of contact pads therein may be collectively referred to as hybrid bonding surface region of a substrate, a layer, or an element.

In some embodiments, the nonconductive material of the first element can be directly bonded to the corresponding nonconductive material of the second element using dielectric-to-dielectric bonding techniques (e.g., low temperature covalent bonding). In some cases, a first bonding region may have a first bonding surface and a second bonding region may have a second bonding surface. For example, dielectric-to-dielectric bonds may be formed between the first bonding surface of the first element and the second bonding surface of the second element without an adhesive using the direct bonding techniques disclosed at least in U.S. Pat. Nos. 9,564,414; 9,391,143; and 10,434,749, the entire contents of each of which are incorporated by reference herein in their entirety and for all purposes.

In some examples, the bonding surface of the dielectric bonding regions can be polished to a high degree of smoothness (e.g., to improve a dielectric-to-dielectric bond). The bonding surfaces can be cleaned and exposed to a plasma and/or etchants to activate the surfaces. The activation process may enable or facilitate direct dielectric-to-dielectric bonding process. In some embodiments, the activated bonding surfaces or the field area can be terminated with suitable species, such as a nitrogen species.

Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. Further, in some embodiments, the bonding surfaces can be exposed to fluorine. For example, there may be one or multiple fluorine peaks near layer and/or bonding interfaces. Thus, in the directly bonded structures, the bonding interface between two dielectric materials can comprise a very smooth interface with higher nitrogen content and/or fluorine peaks at the bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes. In various embodiments, the bonding surface prepared by the procedure described above may enable forming a bond between the first and the second element without an intervening adhesive.

In some embodiments, a dielectric layer may include one or more conductive contact pads. A conductive contact pad (also referred to as “contact pad”) comprises a conductive material (e.g., copper, nickel, gold, or a metal alloy) and may be embedded in the dielectric layer. In some examples, a conductive contact pad may comprise a conductive bonding surface (e.g., a polished conductive surface) that can form a bond with the conductive bonding surface of another conductive contact pad without an adhesive. The bond formed between two contact pads (e.g., via their conductive bonding surfaces), can be an electrically conductive bond. In some embodiments, the conductive pads or features of the bonding surface of the first substrate or element may comprise a material different from a material used to form the conductive pads or features of the bonding surface of the second substrate or element.

In some cases, a surface that comprises the bonding surface (dielectric bonding surface) of the dielectric layer and the conductive bonding surface of the conductive contact pad, may be referred to as a hybrid bonding surface. In various embodiments, two hybrid bonding surfaces may form hybrid direct bonds between the first and the second elements without an intervening adhesive. The hybrid direct bond may formed such that a first dielectric bonding surface of the first element is bonded to a second dielectric bonding surface of second element, and a first conductive bonding surface of the first element is bonded to a second conductive bonding surface of the second element to electrically connect a first contact pad of the first element to a second contact pad of the second element. In some cases, after direct bonding, a hybrid bonding interface between a first hybrid bonding surface of the first element and a second hybrid bonding surface of the second element. A hybrid direct bond or hybrid bond may comprise at least one conductive region or contact pad in addition to the dielectric bonding region. In some embodiments, each element may include one or more conductive contact pads. In these embodiments, the conductive contact pads of the first element can be directly bonded to corresponding conductive contact pads of the second element. For example, a hybrid bonding technique can be used to provide conductor-to-conductor direct bonds along a bond interface formed between two conductive bonding surfaces and between covalently direct bonded dielectric-to-dielectric surfaces, prepared as described above. In various embodiments, the conductor-to-conductor (e.g., contact pad to contact pad) direct bonds and the dielectric-to-dielectric direct bonds can be formed using the direct bonding techniques disclosed at least in U.S. Pat. Nos. 9,716,033 and 9,852,988, the entire contents of each of which are incorporated by reference herein in their entirety and for all purposes. Conductive contact pads (which may be surrounded by nonconductive dielectric field regions) may also directly bond to one another without an intervening adhesive.

In some embodiments, the respective contact pads can be recessed below bonding surfaces of the dielectric layer. In some examples, the conductive bonding surface of the contact pads of a dielectric layer can be recessed by less than 30 nm, less than 20 nm, less than 15 nm, or less than 10 nm, for example, or recessed in a range of 2 nm to 20 nm, or in a range of 4 nm to 10 nm, with respect to a bonding surface of the dielectric layer. In some examples, the conductive bonding surface of a contact pad can be recessed below the bonding surface by less than 5 Å, 10Å, 20 Å, or 100Å.

In some embodiments, the dielectric bonding regions are directly bonded to one another without an adhesive at room temperature and, subsequently, the bonded structure is annealed at an elevated temperature (e.g., above room temperature). Upon annealing, the contact pads can expand and contact one another to form a metal-to-metal direct bond. In some embodiments, the directly bonded opposing conductive pads or traces may comprise different types of metals. In some such embodiments, the annealing process may result in formation of bonded pads comprising a metallic alloy.

In some embodiments, the pitch of the contact pads, or conductive traces embedded in the bonding surface of one of the bonded elements, may be less than 40 microns, or less than 10 microns or even less than 1 microns. For some applications, the ratio of the pitch of the contact pads to one of the dimensions of the contact pad (e.g., the width or the length of the contact pad) can be less than 5, or less than 3 and sometimes desirably less than 2. In other applications, the width of a contact pad (e.g., a longitudinal distance between two ends for the contact pad) embedded in the bonding surface of one of the bonded elements may range between 0.3 to 30 microns. In various embodiments, the contact pads and/or traces can comprise copper or silver, gold, tin, nickel, carbon or an alloy comprising these materials although other conductive materials may be suitable.

The direct bonding processes described above typically utilize one or more inorganic dielectric layers as the bonding layer that forms dielectric-to-dielectric direct bonds. However, unlike direct bonding processes, in some embodiments, one or both elements can comprise an organic dielectric bonding layer (referred to herein as an “organic chemical bonding process”). For example, in some embodiments, both elements to be bonded can comprise respective organic dielectric bonding layers (such as polyimide or benzocyclobutene (BCB)). The organic bonding layers on each element can be the same material or different materials. In other embodiments, one element can comprise an organic dielectric bonding layer and the other element can comprise an inorganic dielectric bonding layer.

In such organic bonding processes, both elements can be planarized as explained above. Prior to bonding, the organic layer(s) can be at least partially (e.g., fully) cured so as to form a hardened bonding surface for planarization. Thus, in organic bonding processes, the organic bonding layer(s) may not be in a flowable state at the time of bonding. For elements with organic bonding layers, the polishing process may result in planarized surfaces that are sufficiently planar so as to form a bond with the opposing element. For example, in embodiments in which an organic layer is planarized, the planarized surface can have a surface roughness in the range of 0.3 nm to 2 nm. In some embodiments, organic bonding layers may not be planarized at all. As explained above, in various embodiments, organic bonding layer(s) of one or both elements can be activated and/or terminated with a suitable species, e.g., utilizing a nitrogen-containing and/or water-containing plasma activation process. The elements with one or more organic bonding layers can be brought into contact at room temperature to form dielectric-to-dielectric bonds (e.g., organic-to-organic or organic-to-inorganic bonds). The strength of the bonds (which can comprise covalent bonds) can be, for example, in a range of 1000 mJ/m² to 4000 mJ/m².

In some organic bonding processes, conductive contact features can be at least partially embedded in the organic bonding layer(s). To effectuate contact between opposing contact features, the elements can be annealed, e.g., at a temperature below the glass transition temperature or melting point of the organic material(s) used in the bonding layer(s), such that the organic material does not melt or otherwise flow across the initial dielectric bond interface.

Thus, in direct hybrid bonding processes (herein referred to as direct bonding), the dielectric bonding regions and the contact pads of a first element can be directly bonded to those of a second element without an intervening adhesive and form a bonded structure. In some arrangements, the first element can comprise a singulated element, such as a singulated integrated device die. In other arrangements, the first element can comprise a carrier or substrate (e.g., a wafer) that includes a plurality (e.g., tens, hundreds, or more) of device regions that, when singulated, form a plurality of integrated device dies. Similarly, the second element can comprise a singulated element, such as a singulated integrated device die. In other arrangements, the second element can comprise a carrier or substrate (e.g., a wafer).

Various embodiments disclosed herein relate to hybrid bonded structures in which at least two elements are hybrid bonded to one another without an intervening adhesive. Such hybrid bonded structures, which can comprise direct hybrid bonds, may be referred to as Direct Bond Interconnects (DBI®). In particular, hybrid bonded structures having one or more conductive interconnects (or vias) formed by direct bonding of conductive contact pads and at least one flexible region or layer are described.

In some embodiments, at least one element may comprise a flexible region or a flexible layer, a hybrid bonding surface, and one or more conductive contact pads (herein referred to as contact pads). In some examples, a flexible substrate or a flexible layer may comprise a flexible or deformable material. In some examples, a flexible substrate or a flexible layer may be a flexible region comprising a deformable material. In some examples, a flexible substrate or a flexible layer may be composed of a flexible or deformable material (e.g., an organic material).

In some embodiments, a first hybrid bonding surface can be formed on a flexible layer or a flexible substrate. In some such embodiments, the flexible region or section of the flexible substrate or layer may comprise at least a portion of the hybrid bonding surface and at least one of the contact pads. In some cases, the one or more contact pads can be electrically connected to conductive traces and/or vias that are at least partially embedded in a flexible region of a flexible substrate or layer.

In some embodiments, another layer or a die (e.g., a component such as an electronic component) comprising a second hybrid bonding surface and at least one second contact pad may be directly bonded to the first hybrid bonding surface of the flexible layer or substrate. The die may comprise an integrated electronic device (e.g., a semiconductor electronic device). In some cases, the die may be hybrid bonded on the flexible layer or substrate to electrically connect the die to another die hybrid bonded to the flexible substrate or layer, or to another layer or substrate. Advantageously, the flexible portion of the flexible substrate (or layer) may provide a mechanically flexible electrical connection between the two dies, two layers, two substrates, a die and a substrate, and the like, allowing them to move with respect to each other (e.g., due to thermal expansion) while being electrically connected.

In some cases, the other element can be a second substrate (e.g., a second flexible substrate) comprising a hybrid bonding surface and a second contact pad. The second substrate may further comprise conductive traces and vias configured to electrically connect the second contact pad and one or more other contact pads of the second substrate. In some embodiments, the second substrate may comprise a flexible region or layer. In some examples, the second substrate may be composed of a flexible (or deformable) material.

As mentioned above a flexible layer, substrate, or region may comprise a flexible, deformable, or otherwise compliant material. In some embodiments the deformable material can be an organic material comprising a polymer (e.g., liquid crystal polymer and/or a polyimide). In some cases, the deformable material can be transparent in the visible and infra red light. For examples, a flexible layer may have an optical transmission larger than 30%, 40%, 50%, 60%, 70%, 80%, or larger values in a wavelength range from 450 nm to 1200 nm, from 500 nm to 1000, or from 400 nm to 800 nm.

In some embodiments, two or more substrates may be stacked on or bonded (e.g., hybrid bonded) to one another to form a bonded structure and allow electrical contact between one or more conductive lines in a first element (e.g., a first die) and one or more conductive lines in a second element (e.g., a second die). In some embodiments, two or more substrates may be stacked on or bonded (e.g., hybrid bonded) to one another to form a bonded structure and allow electrical or optical pathway or both between a first element (e.g., a first die) and a second element (e.g., a second die). Conductive contact pads of the first element may be electrically connected to corresponding conductive contact pads of the second element via the conductive pads and conductive lines of the intervening substrates. Any suitable number of elements (e.g., layers) can be stacked to form a multilayer bonded structure. Any number of layers or substrates can be stacked (e.g., daisy-chained together) to form a layered structure of any suitable thickness or dimension. In some embodiments, at least one of the layers in the stack of layers may comprise a flexible region (or layer) or a core layer composed of a flexible (deformable) material.

Advantageously, a flexible substrate or layer, may reduce a mechanical coupling between the first element and the second element such that a change in the dimensions, or position of the first element or a change of strain in a region of the first element (e.g., due to temperature changes or a mechanical force) of the first element is different from the resulting change in the dimensions, or position of the second element or the resulting change of strain in a region of the second element. In some embodiments, the radius of curvature of a bent flexible substrate can be less than 100 times the thickness of a thickness of the substrate, less than 50 times a thickness of the substrate and even less than 20 times a thickness of the substrate. Moreover, the use of flexible substrate(s) can beneficially improve the utility of integrated devices and packages. For example, the flexible substrate(s) can be bent or deformed when subject to relatively small forces (e.g., forces imposed by typical human, manual, or robotic exertion) so as to enable the positioning of the substrate(s) (and therefore the devices mounted thereto) at arbitrary orientations and configurations.

A substrate or layer that includes a flexible region or layer, a contact pad, and a hybrid bonding surface may be referred to as a flexible hybrid bonding substrate or layer. In other words, a flexible hybrid bonding substrate is a flexible substrate having a hybrid bonding layer. A structure or stack (e.g., a structure or stack described above) that comprises at least one element having a flexible region or layer, hybrid bonded to another element, which may or may not include a flexible region or layer, may be referred to as a flexible bonded structure. For examples, one or more dies hybrid bonded to a flexible hybrid bonding substrate may form a flexible bonded structure.

In some cases, a flexible layer or substrates (e.g., a hybrid flexible layer or substrate) may be included in a structure, device, part, or component used in an application where at least a portion of the structure, device, part, or component can move, be stretched, bent, or otherwise deformed during at least a portion of an operational period. Nonlimiting examples of such devices or components may include sensors on a wristband or ring configured for heart rate monitoring (or other health related monitoring), signal emitters arranged on wearable structures to emit signal locations for tracking the wearer's movements, or the like.

The flexible hybrid bonding substrates and layers and the corresponding flexible bonded structures (e.g., comprising one or more dies hybrid bonded to a flexible hybrid bonding substrate) described below, may allow non-planar die and/or height variation without disrupting electrical connection between components. In some embodiments, multilayer flexible hybrid bonding substrates or layers can provide a higher tolerance of non-planar die and/or height variation compared to single layer flexible bonded structures.

In some embodiments, a hybrid bonding substrate or layer (e.g., a flexible hybrid bonding substrate or layer) may include a main portion and at least one branch portion extending away from the main portion. Such hybrid bonding substrate may be referred to as a hybrid bonded branched substrate or a branched hybrid bonding substrate or a branched flexible hybrid bonding substrate in cases where the hybrid bonding substrate comprises a flexible layer). The main portion may extend from a first end to a second end in a first direction and the branch portion extending from a third end to a fourth end in a second direction. In some cases, the first direction can be perpendicular to the second direction or a projection of the second direction on a plane parallel to a major surface of the main portion. In some cases, the first and second directions can be substantially parallel to a major surface of the main portion. In some cases, the main portion can be a longitudinally extended portion and the branch portion can be a laterally extended portion.

In some cases, the main portion can include a first conductive line at least partially embedded in the main portion and the branch portion can include a second conductive line at least partially embedded in the branch portion. The first and second conductive lines can be electrically connected via a conductive junction or interface near a boundary between the branch portion and the main portion. In some examples, the main portion and the branch portion may have hybrid bonding surfaces configured to allow direct bonding of one or more components to the main and branch portions. In some cases, a conductive region of a hybrid bonding surface of the main portion can be electrically connected to a conductive region of the first conductive line and a conductive region of a hybrid bonding surface of the branch portion can be electrically connected to a conductive region of the second conductive line. The branched hybrid bonding substrate (e.g., branched flexible hybrid bonding substrate) may provide electrical connection between a component hybrid bonded to the branch portion and a component hybrid bonded to the main portion via the first and second conductive lines.

In some embodiments, one or both of the main portion and the branch portion may comprise a flexible layer comprising a deformable region. As described above in some cases, the deformable region may comprise an insulating organic material (e.g., a polymeric material). In some cases, Young's modulus of the flexible layer or the deformable region can be from 1 GPa to 5 GPa, 5 GPa to 15 Gpa, 15 to 50 Gpa, or any ranges formed by these values In some cases, the deformable region can have CTE of less than 15 ppm/° C., from 15 to 20 ppm/° C., from 20 to 30 ppm/° C., from 30-40 ppm/° C., from 40 to 50 ppm/° C., from 50 to 60 ppm/° C. In some embodiments, the deformable region can be configured to allow a first region of the second hybrid bonding surface (of the branch portion) to be displaced with respect to a second region of the first hybrid bonding surface (of the main portion) by an amount larger than 5% of a distance between the first and the second regions without disrupting an electrical connection between the conductive portions of the first and second regions. In some embodiment the radius of curvature of a bent flexible substrate can be less than 100 times the thickness of a thickness of the substrate, less than 50 times a thickness of the substrate and even less than 20 times a thickness of the substrate without disrupting an electrical connection. [In some cases, the first region may comprise a first hybrid bonding interface and the second region may comprise a second hybrid bonding interface. In some such cases, the first and/or the second hybrid bonding interfaces may comprise hybrid bonding interface between the main and/or the branch portion and one or more components (e.g., dies, semiconductor components, and the like).

In some embodiments, the branch and main portions of a branched hybrid bonding substrate may be separate portions connected via a hybrid bonding interface. For example, a branched hybrid bonding substrate maybe formed by fabricating a main portion having a first hybrid bonding surface, fabricating a branch portion having a second hybrid bonding surface, and directly bonding a region of the first hybrid bonding region to a region of the second hybrid bonding surface.

Advantageously, forming a branched hybrid bonding substrate by directly bonding a main substrate and a branch substrate can reduce an area that is lithographically patterned to fabricate the branched substrate and thereby reduces the fabrication cost. For example, in some cases, the main portion and the branch portion can be portions separated from one or more master hybrid bonding substrates each having a hybrid bonding surface. In some cases, a master hybrid bonding substrate can have an elongated shape and the branch and main portions can be different longitudinal portions of the master substrate. As such, in some cases, the area of master substrate can be substantial equal or close to the area of the resulting branched hybrid bonding substrate (formed by directly bonding the main and branch portions). However, when a branched hybrid bonding substrate is formed by tailoring a master hybrid bonding substrate, e.g., by selectively removing some portions of the master substrate such that the remaining potion is a branched hybrid bonding substrate, the removed portions may be waisted, and the area of the resulting branched hybrid bonding substrate can be significantly smaller than the master hybrid bonding substrate.

The proposed fabrication method lends itself to large substrate and panel processing in that the main substrate and the branch substrate can be portions of a large substrate separated after fabricating the panel.

Some of the disclosed embodiments may be used to form a branched flexible hybrid bonding substrate by directly bonding a main flexible hybrid bonding substrate and a branch flexible hybrid bonding substrate separated from a larger master (initial) flexible hybrid bonding substrate.

### Example Flexible Hybrid Layers and Substrates

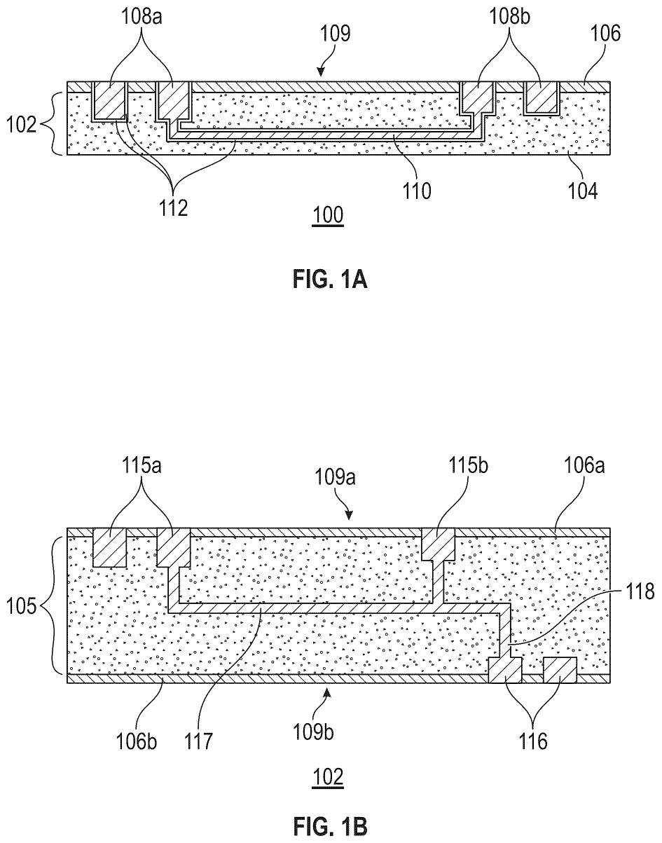

FIG. 1A schematically illustrates an example flexible hybrid bonding substrate (or layer) 100 comprising a flexible layer 102 and a dielectric bonding layer 106 (also referred to as dielectric layer) disposed on the flexible layer 102. The flexible hybrid layer 102 further comprises two or more contact pads 108a, 108b at least partially formed in the flexible layer 102 and extending through the bonding layer 106 to a hybrid bonding surface 109 of the dielectric layer 106. In some cases, the flexible layer 102 may comprise an organic material and the dielectric layer 106 may comprise an inorganic dielectric material (e.g., silicon oxide, silicon nitride, silicon oxynitride, silicon oxynitrocarbide, silicon carbide, spin-on-glass etc.). In some embodiments, a contact pad 108a in the first section of the flexible hybrid bonding substrate 100 may be electrically connected to a contact pad 108b in the second section of the flexible hybrid bonding substrate 100 via a conductive line 110 embedded in the flexible layer 102. In some embodiment, the conductive line 110 may comprise a multilayer conductive lines. In some such embodiments, flexible hybrid bonding substrate (or layer) 100 may electrically connect a first component that is electrically connected to the first contact pad 108a to a second component that is electrically connected to a second contact pad 108b. The first component may be hybrid bonded to a first region of the hybrid bonding surface 109 above the first section and the second component may be hybrid bonded to a second region of the hybrid bonding surface 109 above the second section. In some examples, the conductive line 110 is at least partially embedded in the flexible layer 102. In some embodiments, a barrier layer 112 may separate contact pads 108a, 108b and/or a conductive line 110 of the flexible hybrid layer 102 from the flexible layer 104. For example, the contact pads 108a, 108b, and/or the conductive line 110 may be formed in an opening having a barrier layer lining. In some examples, the barrier layer 112 may comprise a dielectric material. In some cases, the dielectric bonding layer 106 and barrier layer 112 may comprise substantially the same material (e.g., a dielectric material) or have similar compositions. In some cases, the dielectric bonding layer 106 and barrier layer 112 may comprise different material or have different compositions. In some embodiments, the barrier layer 112 may comprise a conductive material. In some examples, the barrier layer 112 may be configured to protect the corresponding contact pad by blocking or reducing transport of the certain species (e.g., water molecules or gas) from the flexible layer 102 to the contact pad and vice versa. In some examples, the barrier layer 112 can prevent copper migration from the contact pads 108a, 108b and the conductive line 110 into the flexible layer 102 and the dielectric bonding layer 106. In some embodiments, the dielectric bonding layer 106 may comprise two or dielectric sub-layers. For example, the dielectric bonding layer 106 may comprise a first dielectric sub-layer (e.g., an intermediate or coupling sub-layer) disposed directly on the flexible layer 102 and a second dielectric sub-layer (e.g., a bonding sub-layer) may be disposed over the coupling dielectric.

In some cases, at least a portion of the flexible layer 102 extending from the first section to the second section of the flexible hybrid layer 102 may comprise a flexible, mechanically deformable, or otherwise a compliant material as described above. Advantageously, the double-sided flexible hybrid bonding substrate (or layer) 100 may provide a deformable electrical connection between two, three, or more components hybrid bonded to different regions of the surface 109.

FIG. 1B schematically illustrates another example double-sided flexible hybrid bonding substrate (or layer) 102 comprising a flexible layer 105, and two dielectric layers (dielectric bonding layers) 106a, 106b, disposed on opposite main surfaces of the flexible layer 105. In some cases, the flexible layer 105 may comprise an organic material and the dielectric layers 106a, 106b may comprise inorganic dielectric materials. The first dielectric layer 106a may comprise a first hybrid bonding surface 109a comprising top surfaces of one or more contact pads 115a, 115b that are at least partially formed in an upper portion of the flexible layer 105. The second dielectric layer 106b may comprise a second hybrid bonding surface 109b comprising top surfaces and one or more contact pads 116 that are at least partially formed in a lower portion of the flexible layer 105. In some embodiments, the contact pad 115a formed in a first section of the upper portion of the flexible layer 105 may be electrically connected to the contact pad 115b formed in a second section of the upper portion of the flexible layer 105 via a conductive line 117. In some cases, the first section may be separated from the first section in a longitudinal direction parallel to a main surface of the flexible layer 105. In some embodiments, a contact pad 115a in the lower portion of the flexible layer 105 may be electrically connected to the contact pad 115b a conductive line 118 and the conductive line 117. Advantageously, the double-sided flexible hybrid bonding substrate (or layer) 102 may provide a deformable electrical connection between two, three, or more components hybrid bonded to different regions of the first and second hybrid bonding surfaces 109a, 109b. For example, the flexible hybrid bonding substrate (or layer) 102 may electrically connect first, second, and third components electrically connected to the contact pad 115a, contact pad 115b, and contact pad 116, respectively. The first and second components may be hybrid bonded to first and second regions of the first hybrid bonding surface 109a, respectively, and the third component may be hybrid bonded to a region of the second hybrid bonding surface 109b. In some cases, the second, and third components, may be placed at different vertical and lateral positions with respect to the first components. In some cases, the vertical and lateral positions may be defined with respect to a main plane or surface of the first components.

It should be understood that the single or double-sided flexible hybrid bonding substrates are neither limited to the specific designs shown in FIGS. 1A-1B nor to configurations that include at least some of the features of these designs with respect to number of layers, placement of the contact pads, a number and/or location of flexible layers or deformable regions. Other examples of substrates and designs that may be used to fabricate the branched layers, substrates, and structures described herein are discussed in U.S. patent application Ser. No. 18/991,032, filed on Dec. 20, 2024, entitled “COMPOSITE HYBRID STRUCTURES,” which is hereby incorporated by reference herein in its entirety

### Example Branched Flexible Substrates

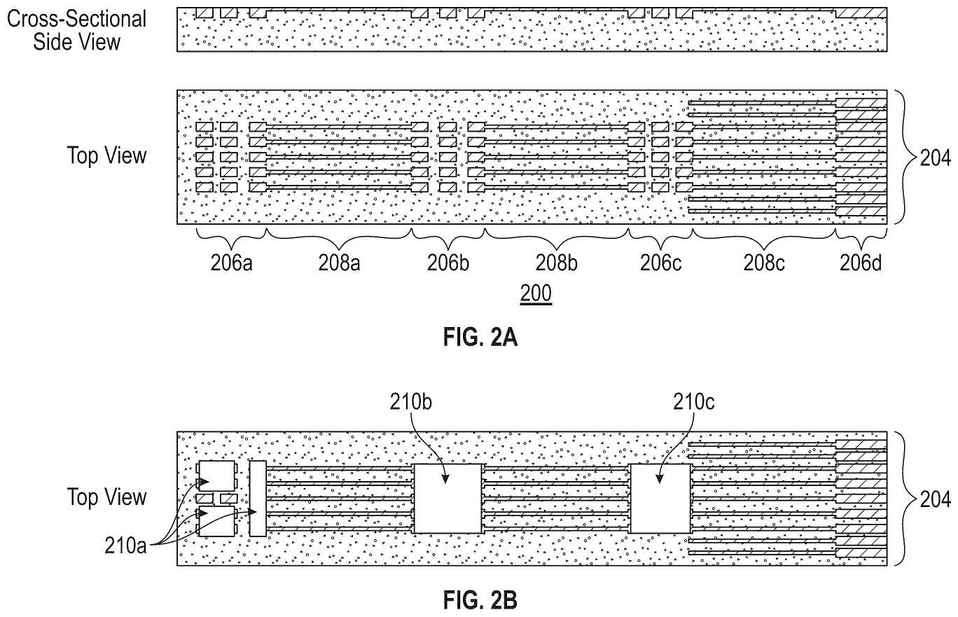

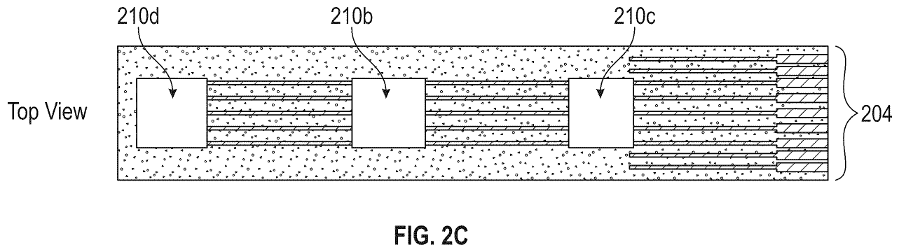

FIG. 2A schematically illustrates an example flexible hybrid bonding substrate 200 depicting a cross-sectional side view of the flexible hybrid bonding substrate 200 (top panel), and a top view of the flexible hybrid bonding substrate 200 (bottom panel). In some embodiments, at least the top major surface of the flexible hybrid bonding substrate 200 comprises a hybrid bonding surface region. In some cases, the top and bottom major surfaces of the flexible hybrid bonding substrate 200 each may comprise a hybrid bonding surface region. In the example shown, the top surface of the flexible hybrid bonding substrate 200 comprise a plurality of (e.g., four) hybrid bonding regions 206a, 206b, 206c, 206d. In some examples, each hybrid bonding surface region may comprise a group of contact pads. In some cases, the contact pads of the hybrid bonding surface regions 206a, 206b, 206c may be configured for direct bonding to one or more components (e.g., electronic components) and the contact pads or terminals 204 of the hybrid bonding surface region 206d may be configured for direct bonding to contact pads of a component or another substrate (e.g., another flexible hybrid bonding substrate). In some cases, one or more contact pads of hybrid bonding surface regions 206a, 206b, 206c, 206d may be electrically connected to one or more contact pads of another hybrid bonding surface region 206a, 206b, 206c, 206d via one or more conductive lines 208a, 208b, 208c of flexible hybrid bonding substrate 200. A conductive line of the flexible hybrid bonding substrate 200 can be at least partially embedded in a dielectric layer (e.g., a dielectric bonding layer, or a flexible layer) of the flexible hybrid bonding substrate 200. In the example shown some contact pads of the hybrid bonding surface region 206a are electrically connected to some of the contact pads of the hybrid bonding surface region 206b, some contact pads of the hybrid bonding surface region 206b are electrically connected to some of the contact pads of the hybrid bonding surface region 206c, and some contact pads of the hybrid bonding surface region 206c are electrically connected to some of the contact pads of the hybrid bonding surface region 206d.

FIG. 2B schematically illustrates an example flexible bonded structure comprising the flexible hybrid bonding substrate 200 and five components (e.g., dies) hybrid bonded to three different hybrid bonding surface regions thereon. In this example, a first, second, and third components 210a, 210b, 210c are hybrid bonded to the first hybrid bonding surface region 206a, a fourth component 210b is hybrid bonded to the second hybrid bonding surface region 206b, and a fifth component 210c is hybrid bonded to the third hybrid bonding surface region 206c.

FIG. 2C schematically illustrates another example flexible bonded structure comprising the flexible hybrid bonding substrate 200 and three components (e.g., dies) hybrid bonded to three different hybrid bonding surface regions thereon. In this example, a first, component 210d is hybrid bonded to the first hybrid bonding surface region 206a, the fourth component 210b is hybrid bonded to the second hybrid bonding surface region 206b, and the fifth component 210c is hybrid bonded to the third hybrid bonding surface region 206c.

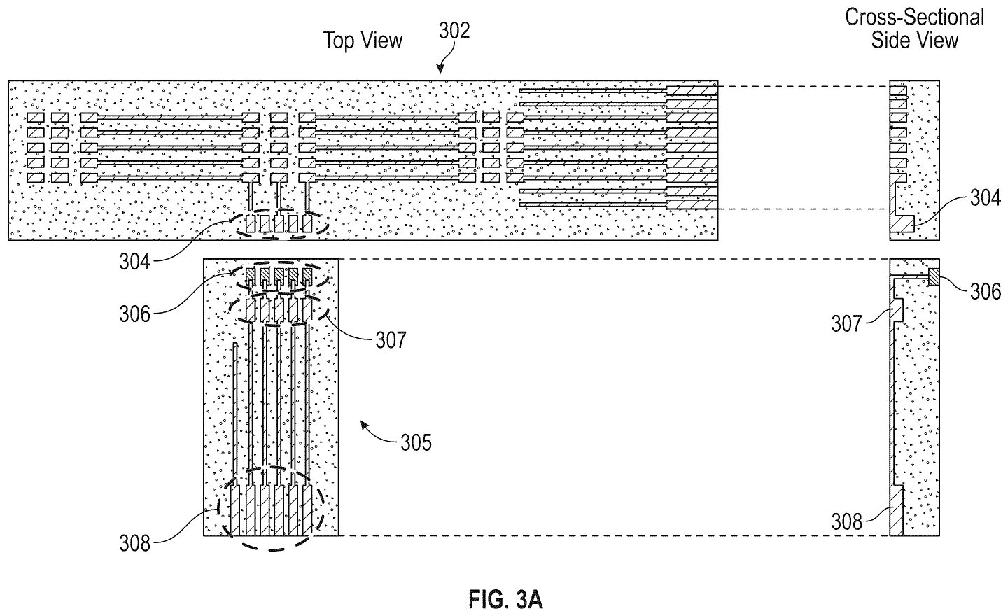

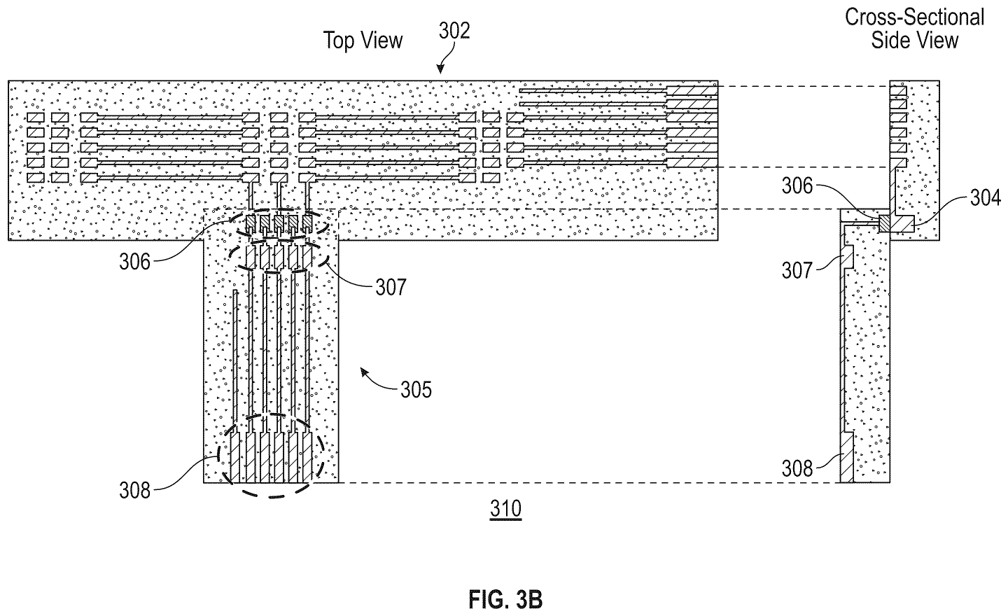

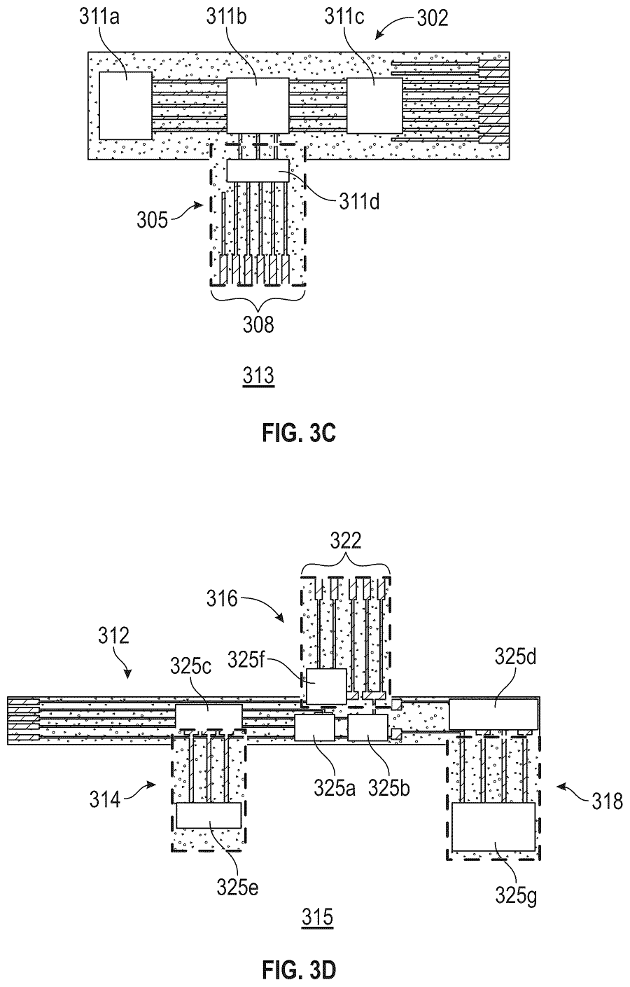

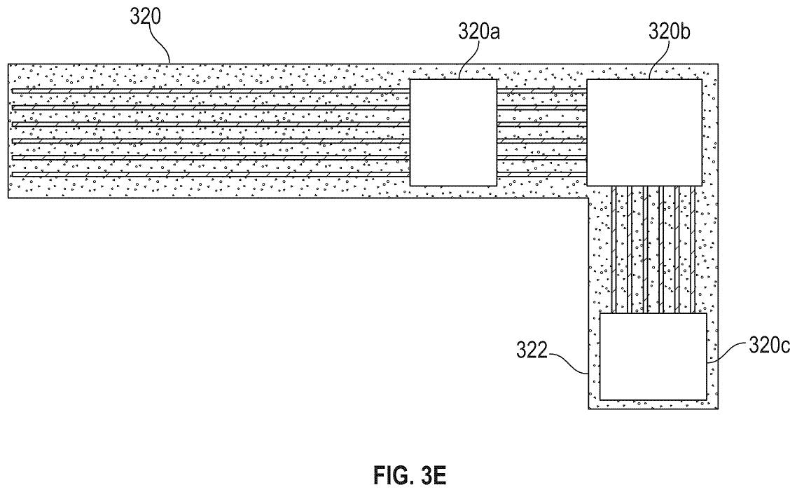

FIG. 3A schematically illustrates top view (left) and side cross-sectional view (right) of the main portion 302 and branch portion 305 of a branched flexible hybrid bonding substrate before formation of the branched flexible hybrid bonding substrate. In some embodiments, the main portion 302 can be a flexible hybrid bonding substrate comprising a hybrid bonding region 304 configured for bonding to a hybrid bonding region of the branch portion 305. In some cases, the main portion 302 may additionally include one or more hybrid bonding regions configured for direct hybrid bonding to one or more components or a substrate different from the branch portion (e.g., another flexible substrate). In some embodiments, the branch portion 305 can be a flexible hybrid bonding substrate comprising a hybrid bonding region 306 configured for bonding to a hybrid bonding region of the main portion 305. In some cases, the branch portion 305 may additionally include one or more hybrid bonding regions 307, 308 configured for direct hybrid bonding to one or more components or a substrate different from the branch portion (e.g., another flexible substrate). In some examples, the branch portion 305 can be a double-sided flexible hybrid bonding substrate where at least one of its hybrid bonding regions is formed on a major surface opposite to a major surface on which the hybrid bonding region 306 is formed for bonding to the main portion 302. In the example shown, the hybrid bonding region 306 is formed on a top major surface of the main portion 302, the hybrid bonding region 306 is formed on a bottom major surface of the branch portion, and two hybrid bonding regions 307, 308 are formed on the top major surface of the branch portion 305.

In various embodiments, one or more contact pads of the main portion 302 can be electrically connected to one or more contact pads of the main portion 302 by one or more conductive lines. In various embodiments, one or more contact pads of the branch portion 305 can be electrically connected to one or more contact pads of the branch portion 305 by one or more conductive lines.

FIG. 3B schematically illustrates a top view (left) and a side cross-sectional view (right) of a branched flexible hybrid bonding substrate 310 formed by directly bonding (e.g., hybrid bonding) the main portion 302 and the branch portion 305 shown in FIG. 3A. In some embodiments, the main portion 302 can be hybrid bonded to the branch portion 305 via a direct bonding interface (e.g., a hybrid bonding interface) formed between the hybrid bonding region 304 and the hybrid bonding region 306. The hybrid bonding interface may provide electrical connection between one or more contact pads of the main portion associated with the hybrid bonding region 304 and one or more contact pads of the branch portion associated with the hybrid bonding region 306.

FIG. 3C schematically illustrates a top view of a branched flexible bonded structure 313 comprising the branched flexible hybrid bonding substrate 310 and four components 311a, 311b, 311c, and 311d hybrid bonded to the three hybrid bonding regions of the branched flexible hybrid bonding substrate 310. In some examples, three components 311a, 311b, 311c are hybrid bonded to the main portion 302 and one component 311d is hybrid bonded to the branch portion 305 of the branched flexible hybrid bonding substrate 310. In some examples, the hybrid bonding interface formed between the main portion 302 and the branch portion 305 may provide electrical connection between the component 311d on the branch portion 305 and the component 311b on the main portion 302.

In various implementations, the components 311a, 311b, 311c, and 311d may comprise a die having a hybrid bonding layer. The die may include a buffer circuit, a control circuit, or other electronic circuits). In some examples, a component may comprise: a passive electronic device (e.g., an inductor) or an active electronic device (e.g., an Integrated Voltage Regulator, IVR, or the like).

FIG. 3D schematically illustrates a top view of a branched flexible bonded structure 315 comprising a branched flexible hybrid bonding substrate and seven components 325a, 325b, 325c, 325d, 325e, 325f, and 325g hybrid bonded to seven hybrid bonding regions of the branched flexible hybrid bonding substrate. In some embodiments, the branched flexible hybrid bonding substrate may comprise a main portion 312 and three branch portions 314, 316, 318, wherein at least one branch portion is hybrid bonded to the main portion 312 via a hybrid bonding interface formed between a hybrid bonding region of the branch portion and a hybrid bonding region of the main portion 312. In some examples, components 325a, 325b, 325c, 325d, are hybrid bonded to the main portion 312, component 325e is hybrid bonded to the first branch portion 314, component 325f is hybrid bonded to the second branch portion 316, and component 325g is hybrid bonded to the third branch portion 318 of the branched flexible hybrid bonding substrate. In some examples, the hybrid bonding interface formed between the main portion 312 and the branch portions 314, 316, and 318 may provide electrical connection between the respective components on these branch portions and a component on the main portion 312.

FIG. 3E schematically illustrates a top view of another branched flexible bonded structure 317 comprising a branched flexible hybrid bonding substrate and three components 320a, 320b and 320c hybrid bonded to three hybrid bonding regions of the branched flexible hybrid bonding substrate. In some embodiments, the branched flexible hybrid bonding substrate may comprise a main portion 320 and one branch portion 322 hybrid bonded to the main portion 320 via a hybrid bonding interface formed between a hybrid bonding region of the branch portion 322 and a hybrid bonding region of the main portion 320.

### Example Bonded Structures With Branched Flexible Substrates

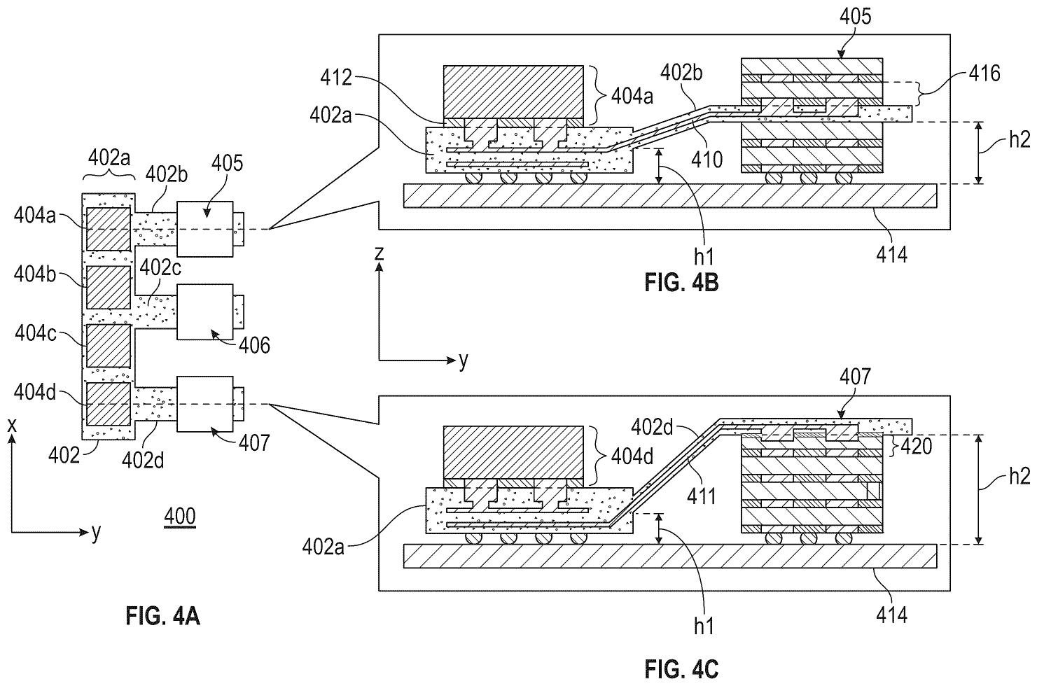

FIG. 4A schematically illustrates a top view of an example branched flexible bonded structure 400 comprising a branched flexible hybrid bonding substrate 402 having a main portion 402a and a plurality of (e.g., three) separate branch portions 402b, 402c, and 402d hybrid bonded to the main portion and extending away from the main portion 402a. In the examples shown, a plurality of components 404a-404d can be hybrid bonded or otherwise mounted or electrically connected to the main portion 402a, and the first, second, and third branches 402b, 402c, 402d, are hybrid bonded to first, second, and third multilayer stacks 405, 406, 407, respectively. In some examples, one of the plurality of components 4046a-404d can be hybrid bonded to the main portion 402a.

In some embodiments, the plurality of components 404a-404d may comprise large components (e.g., passives or active chips) that are space constrained by being large and/or thick. For example, one or more the plurality of components 404a-404d may comprise: a passive electronic device (e.g., an inductor) or an active electronic device (e.g., an Integrated Voltage Regulator, IVR, or the like). In some cases, one or more of the plurality of components 404a-404d may comprise a die (e.g., a buffer circuit, a control circuit, or other integrated electronic circuits) or a memory or storage die. In various implementations, the plurality of components 404a-404d, may comprise a dielectric bonding layer configured for hybrid bonding.

In some cases, at least one of the branches of a branched flexible hybrid bonding substrate may be hybrid bonded to one or more sublayers of a component or die that comprises a stack of multiple layers (herein referred to a multilayer stack). In the example shown in FIG. 4A the first and third branches 402b, 402d, are hybrid bonded to two multilayer stacks 405, 407. The die may include a buffer circuit, a control circuit, or other electronic circuits. In some examples, a layer of stack may include an electronic chip or device sandwiched between two other layers that may include other chips.

In some embodiments, at least one of the plurality of components 404a-404d can be a large component (e.g., a large inductor or an IVR) that cannot be inserted in a stack (e.g., multilayer stacks 405, 407). Advantageously, in these embodiments, the branched substrate (e.g., flexible branched substrate) formed by hybrid bonding the main portion 402a and branched portions 402b, 402c, 402d may allow the large component to be electrically connected to a multilayer stack. In some examples, when a branch potion comprises a flexible layer through which the electrical connection between the large component bonded to or mounted on the main portion 402a and the multilayer stack is provided, electrical connection can be established between the large component and a desired layer of the multilayer stack being at a different vertical position with respect to the large component.

In some embodiments, a multilayer stack may comprise a stack of device dies bonded (e.g., hybrid bonded) together. In some examples, the stacks 405-407 can comprise stack of memory dies, while the dies 404a-404c can comprise processor dies electrically connected to the memory dies.

FIG. 4B schematically illustrates a cross-sectional side view of the flexible bonded structure 400 across the first branch portion 402b showing the first component 404a hybrid bonded to the main portion 402a of the branched flexible bonded structure 400 and the first branch portion 402b hybrid bonded to at least one sublayer 416 of the first multilayer stack 405 below a top layer and above a bottom layer. For example, in FIG. 4C, the first branch portion 402b is sandwiched between sublayers 416 of the first multilayer stack 405. FIG. 4C schematically illustrates a cross-sectional side view of the flexible bonded structure 400 across the third branch portion 402d showing the component 404d bonded to the main portion 402a of the branched flexible bonded structure 400 and the second branch portion 402d bonded to a top layer 420 of the first multilayer stack 405. In other embodiments, it should be appreciated that the second branch portion 402d can alternatively be hybrid bonded to a bottom layer of the stack 405.

In some examples, a branch portion may be hybrid bonded to at least one layer of the multilayer stack via a hybrid bonding interface. In some embodiments, at least one of the branch portions 402b, 402c, 402d may comprise a flexible layer. In some cases, the flexible layer may comprise flexible hybrid layer having a hybrid bonding surface. The branched flexible bonded structure 400 may further comprise a component bonded (e.g., hybrid bonded) to the main portion 402a. The branched flexible bonded structure 400 may further comprise a component bonded (e.g., hybrid bonded) to the main portion 402a. In some embodiments, the main portion 402a may comprise a hybrid layer having a hybrid bonding surface. In some cases, the hybrid layer may comprise a flexible hybrid layer having a flexible layer. In some cases, the component may be hybrid bonded on a hybrid surface of the main portion 402a.

In some examples, a branch portion may extend from a first end closer to the main portion to a second end farther from the main portion. In some cases, at least the second end of each branch portion is separated from the second end of another branch portion with a gap (e.g., air gap). In some cases, a multilayer stack can be bonded to a region of the branch portion closer to the second end compared to the first end. In some cases, the main portion 402a may extend in a longitudinal direction (e.g., substantially parallel to x-axis) and a branch portion may extend in a lateral direction (e.g., substantially parallel to y-axis) perpendicular to the longitudinal direction. In some cases, an individual branch portion may be laterally separated from the immediately adjacent branch portions by a gap (e.g., an air gap). In some examples, the main portion may have a first width along the lateral direction and a branch portion may have a second width along the longitudinal direction. The first width can be larger or smaller than the second width. In some examples, the first width can be substantially equal to the second width. In some examples, the main portion may have a first length along the longitudinal direction and a branch portion may have a second length along the lateral direction. The first length can be larger or smaller than the second length. In some examples, the first length can be substantially equal to the second length. In some implementations, one or both of first and second length can be from 1 centimeter to 55 centimeters. In various implementations, one or both of first and second width can be from 5 centimeters to 40 centimeters.]

In the example shown in FIG. 4A four components 404a, 404b, 404c, and 404d are bonded (e.g., hybrid bonded) to the main portion 402a, a first multilayer stack 405 is bonded (e.g., hybrid bonded) to a first branch portion 402b, a second multilayer stack 406 is bonded (e.g., hybrid bonded) to a second branch portion 402c, a third multilayer stack 407 is bonded (e.g., hybrid bonded) to a third branch portion 402d. Each of the first, second, and third branch portions 402b, 1402c, 402c, are extended from a first end connected, attached, or bonded to the main portion 402a to a second end bonded to the respective multilayer stack. In some embodiments, the first end may be hybrid bonded to the main portion 402a via a hybrid bonding interface.

The first branch portion 402b may comprise a flexible hybrid layer having a hybrid bonding surface hybrid bonded to an intermediate layer 416 of the first multilayer stack 405 via at least one hybrid bonding interface. The hybrid bonding interface may be configured to electrically connect one or more contact pads of the intermediate layer 416 to a conductive line 410 on or within the first branch portion 402b. In some cases, the conductive line 410 may electrically connect the first multilayer stack 405 to a first component 404a bonded on the main portion 402a of the branched substrate 402. In some embodiments, the conductive line 410 may comprise a multilayer conductive line comprising two or more metal layer having different composition or properties. In some embodiments, multiple conductive lines may pass through the first branch portion 402b to electrically connect conductive features of the main portion 402a to those of the multilayer stack. In some examples, two or more conductive lines passing through the first branch portion can be interconnected by one or more conductive vias (not shown). In some examples, the first component 404a may be hybrid bonded on the main portion 402a via hybrid bonding interface that electrically connects a contact pad of the first component 404a to a contact pad associated with a hybrid bonding surface of the main portion 402a.

In some embodiments, the third branch portion 402d may comprise flexible hybrid layer having a hybrid bonding surface hybrid bonded to a top layer 420 of the third multilayer stack 407 via at least one hybrid bonding interface. The hybrid bonding interface may be configured to electrically connect one or more contact pads of the top layer 420 to a conductive line 411 on or within the third branch portion 402d. In some cases, the conductive line 411 may electrically connect the multilayer stack 407 to a third component 404d bonded on the main portion 402a of the branched substrate 402. In some examples, the third component 404d may be hybrid bonded on the main portion 402a via hybrid bonding interface that electrically connects a contact pad of the component 404d to a contact pad associated with a hybrid bonding surface of the main portion 402a.

In some embodiments, the main portion 402a of the branched substrate 402 and the first multilayer stack 405 (and/or 407) may be mounted on a common carrier substrate 414. In some cases, the main portion 402a and the first multilayer stack 405 (and/or 407) may be electrically connected to the common carrier substrate 414 via one or more conductive regions, contact pads, electrodes, and the like. In some cases, an electrical connection between one or both of main portion 402a and multilayer stack 405 (and/or 407) and carrier substrate 414 may comprise a solder ball grid array. For example, the carrier substrate may comprise an integrated circuit (IC) or printed circuit board (PCB) having a solder ball grid array configured to electrically connect one or more conductive regions, contact pads, and/or electrodes of one or both of main portion 402a and multilayer stack 405 (and/or 407) and carrier substrate 414 to the IC or PCB. In some such embodiments, a layer of the first multilayer stack 405 (and/or 407) through which the first multilayer stack 405 is electrically connected to the branched structure 400, and the branched structure 400 may be positioned at different distances along a vertical direction (e.g., along z-axis) with respect to the carrier substrate 414. Advantageously, in these embodiments, the flexibility of the branch portion 402b (and/or 402d) and the corresponding conductive lines 410 may allow electrical connection between the first multilayer stack 405 (and/or 407) and the main portion 402a of the branched structure 400. In some examples, a first vertical distance (h1) between the first end of the branch portion 402b (and/or 402d) and a top major surface of the carrier substrate 414 can be different from a second vertical distance (h2) between the second end of the branch portion 402b (and/or 402d) and the top major surface of the carrier substrate 414. In some cases, a percentage difference between h1 and h2 (2×|h2−h1|/(h1+h2)) and h2 can be from 2% to 10% from 10% to 50%, from 50% to 70%, from 70% to 100%, from 100% to 200%, from 200% to 500% from 500% to 1000% or any range formed by the values or larger or smaller values. In some examples, a percentage difference between h1 and h2 can be large that 5%, larger than 10%, larger than 30% or larger than 50%.

In some cases, a branch portion may comprise one or more conductive lines extending from the second end of the branch portion away from the main portion 402a to the second end closer to the main portion 402a and configured to electrically connect a multilayer stack to a component bonded to and/or a conductive line on or within the main portion 402a.

In some embodiments, the branched flexible hybrid bonding substrate 402 may comprise a continuous layer carved or cut out of a primary flexible substrate (e.g., a flexible hybrid bonding substrate). In some such embodiments, fabrication of the branched flexible bonded structure 400 may comprise fabricating a primary flexible hybrid bonding substrate, separating the branched flexible hybrid bonding substrate 402 from the primary flexible hybrid bonding substrate (e.g., using a wafer or polymer cutting tool), bonding (e.g., directly bonding) components 404a, 404b, 404c, and 404d on the main portion 402a of the branched flexible hybrid bonding substrate 402, and bonding the first, second, and third multilayer stacks 405, 406, and 407 on the respective branch portions 402b, 402c, and 402d, respectively. In some embodiments, after separation selected regions of the branched flexible hybrid bonding substrate 402 (e.g., hybrid bonding regions) may be cleaned and activated before bonding the components. In some cases, the separation process may comprise coating a bonding surface of the primary flexible hybrid bonding substrate with a protective layer, separating the branched flexible hybrid bonding substrate 402 from the primary flexible hybrid bonding substrate, e removing (e.g., stripping) the protective layer, cleaning the branched flexible hybrid bonding substrate 402, and preparing selected regions of the branched flexible hybrid bonding substrate 402 for hybrid bonding. In some examples, preparing a region for hybrid bonding may comprise rinsing with DI water and drying the region. In some examples, at least one of the branch portions 402b, 402c, and 402d, may be bonded to the respective multiplayer stack by direct bonding and formation of a hybrid bonding interface. In some examples, at least one of the components may be bonded to main portion 402a by direct bonding and formation of a hybrid bonding interface.

In some embodiments, the branched flexible hybrid bonding substrate 402 may comprise one or more features described above with respect to the branched flexible hybrid bonding substrate 310. For example, the branched flexible hybrid bonding substrate 402 may comprise a main substrate comprising the main portion 402a, and at least one of the branch portions 402b, 402c, and 402d may comprise a flexible substrate (herein referred to as branch substrate) bonded to the main substrate. In some cases, the branch substrate may comprise a flexible hybrid bonding substrate having a hybrid bonding surface configured to be hybrid bonded to the main substrate via a hybrid bonding interface. In some cases, the branch substrate may comprise a flexible hybrid bonding substrate having a hybrid bonding surface configured for direct bonding to a multilayer stack of the multilayer stacks 405, 406, and 407.

In various implementations, a first end of a branch substrate may be hybrid bonded to a top, or bottom hybrid bonding surface of the main portion 402a. A second end of the branch substrate may be hybrid bonded to a top, bottom, or intermediate later of a multilayer stack. For example, the first end of a branch substrate may be hybrid bonded to a top hybrid bonding surface of the main portion 402a and a hybrid bonding surface on the top layer of the multilayer stack.

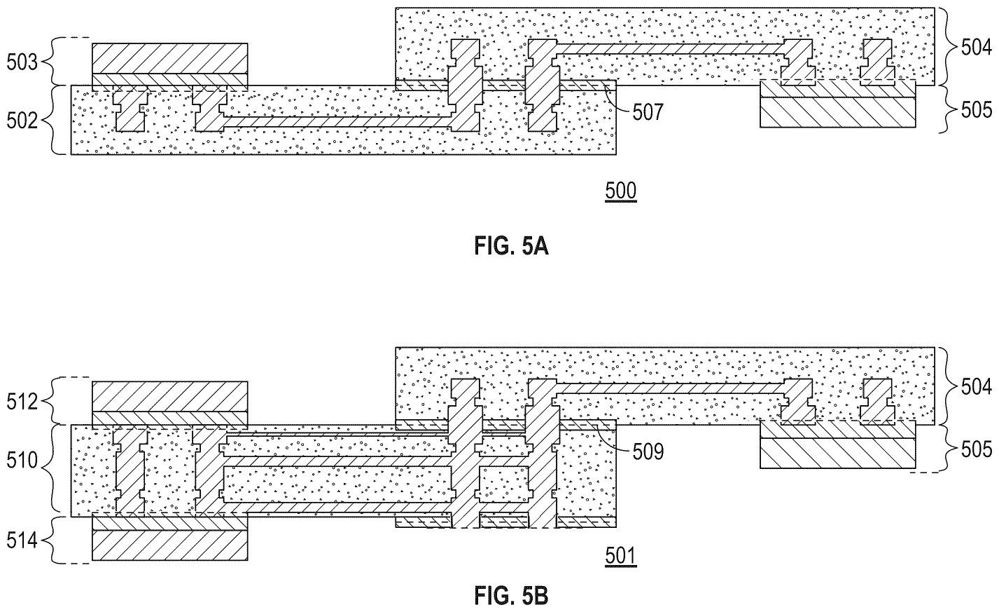

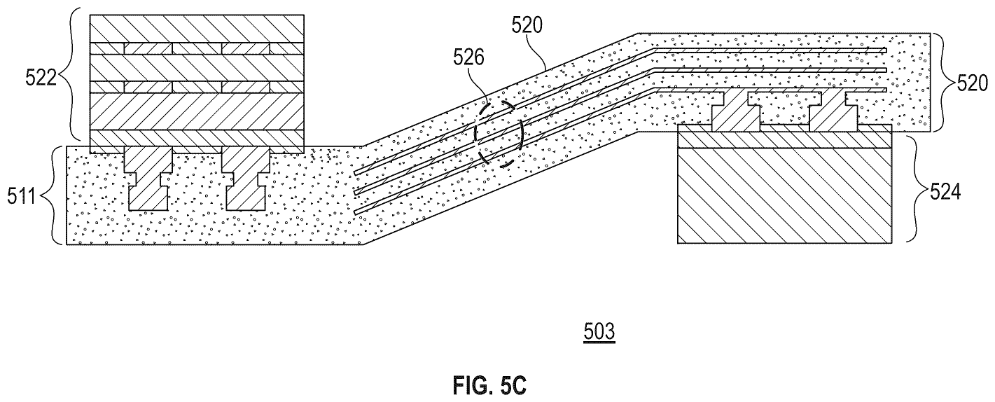

In some embodiments, the main portion 402a and a component or multilayer stack can be hybrid bonded to hybrid bonding surfaces on the same major surface of the branch substrate. FIG. 5A schematically illustrates a side cross-sectional view of a flexible structure 500 formed by directly bonding two flexible hybrid bonding substrates 502, 504, each having one hybrid bonding surface, via a hybrid bonding interface 507. Two components 503, 505 are each hybrid bonded to the hybrid bonding surface of one of flexible hybrid bonding substrates 502, 504. In some examples, hybrid bonding substrate 502 can be a main portion of a branched flexible hybrid bonding substrate and the flexible hybrid bonding substrate 504 can be the corresponding branch portion. In the example shown a first hybrid bonding surface on a bottom surface and close to a first end of the branch substrate 504 is hybrid bonded to a hybrid bonding surface on a top surface of the main substrate 502. The flexible branched structure 500 further comprises a first component 503 hybrid bonded to the main substrate and a second component 505 directly to branch substrate 504. In the example shown a second hybrid bonding surface on the bottom surface and close to a second end of the branch substrate 504 is hybrid bonded to the second component 505.

In some cases, a branch substrate may comprise a double-sided flexible hybrid bonding substrate. In some such cases, the branch substrate may hybrid bonded to the main substrate and a component (e.g., a multilayer stack) via two hybrid bonding surfaces on the opposite major surfaces of the branch substrate (e.g., top and bottom surfaces). FIG. 5B schematically illustrates a side cross-sectional view of a flexible structure 501 formed by directly bonding a flexible hybrid bonding substrate 504 and a double-sided flexible hybrid bonding substrate 510, via a hybrid bonding interface 509. Two component 512, 514 are hybrid bonded to the top and bottom hybrid bonding surfaces of double-sided flexible hybrid bonding substrate 510 and one component 505 is hybrid bonded to the same hybrid bonding surface through which the flexible hybrid bonding substrate 504 is hybrid bonded to the double-sided flexible hybrid bonding substrate 510. In some examples, hybrid bonding substrate 510 can be the main portion of a branched flexible hybrid bonding substrate and the flexible hybrid bonding substrate 504 can be the corresponding branch portion. In the example shown a hybrid bonding surface on a bottom surface and close to a first end of the branch substrate 504 is hybrid bonded to a top hybrid bonding surface of the double-sided main portion 510.

In some cases, two components may be hybrid bonded to opposite hybrid bonding surfaces of a branched flexible hybrid bonding substrate. In some such cases, a branched portion may comprise a flexible layer configured to allow the branch portion to be deformed (e.g., tilted) such that a bottom surface of the main portion and the component bonded to a bottom surface of the branched portion can be positioned in the same plane (e.g., to be mounted on a common surface). FIG. 5C schematically illustrates a side cross-sectional view of a branched flexible bonded structure 503 across a branch portion, the branch portion 520 having a hybrid bonding surface opposing a hybrid bonding surface of the main portion 511. A first component 522 is hybrid bonded on the top surface of the main portion 511 and a second component it is hybrid bonded to bottom surface of the branch portion 520. The first and second components 522, 524 are electrically connected via conductive lines 526 electrically connecting the contact pads to which the first and second components 522, 520 are connected. In some cases, the hybrid bonding interface through which the second component 524 is hybrid bonded to the branch portion 520 may be vertically separated from a bottom portion of the main portion 511 or a surface on which the main portion 511 is mounted. In some such cases, the branch portion 520 may be configured to be deformed (e.g., tilted, or coiled) to maintain electrical connection between the first and second components 524, 522.

In some embodiments, a branch portion (e.g., any one of branch portions 402b, 402d, 520) can be folded, bent, coiled or tilted without damaging the branch portion and without disrupting an electrical connection between a component hybrid bonded on the main portion and another component hybrid bonded to the branch portion via the folded or bent, coiled or tilted branch portion. In some examples, an acute angle between the branch (e.g., any one of branch portions 402b, 402d, 520) and a main portion (e.g., main portion 402a or 511) can be from 10 to 20 degrees, from 20 to 30 degrees, from 30 to 40 degrees, from 40 to 50 degrees, from 50 to 60 degrees or any range formed by these values or larger or smaller values.

### Fabrication Steps

As described above in some embodiments, a branched flexible hybrid bonding substrate may comprise a main flexible hybrid bonding substrate and another flexible hybrid bonding substrate (or layer) hybrid bonded to the main flexible hybrid bonding substrate via a hybrid bonding interface. In some implementations, the main flexible hybrid bonding substrate and the other flexible hybrid bonding substrate (or layer) can be separated portions of a single flexible bonded structure. In some cases, the main flexible hybrid bonding substrate and the other flexible hybrid bonding substrate (or layer) can be fabricated separately and/or can be separated portions of two different flexible bonded structures. Nonlimiting example methods for fabricating a branched flexible bonded structure are disclosed below.

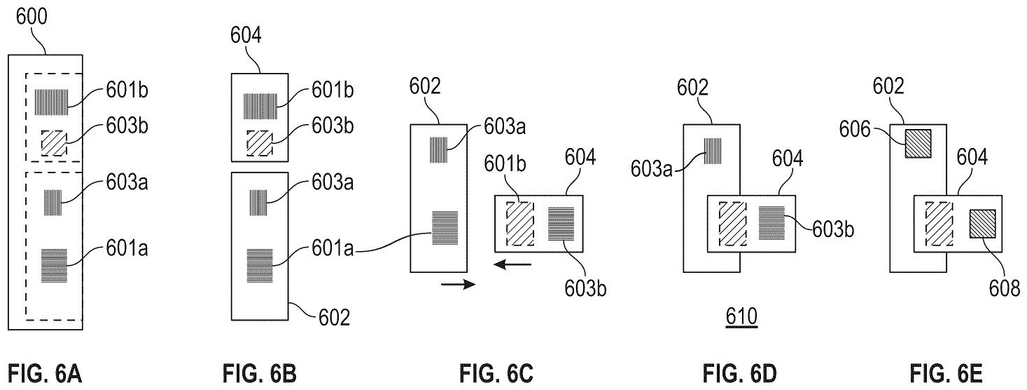

FIG. 6A to 6D schematically illustrate selected steps of an example process for fabricating a branched flexible hybrid bonding substrate.

At a first fabrication step (FIG. 6A), at least one primary flexible hybrid bonding substrate 600 is provided. In some examples, the primary flexible hybrid bonding substrate 600 may comprise one or more features described above with respect to flexible hybrid bonding substrate 100 and 200. In some embodiments, the primary flexible hybrid bonding substrate 600 may comprise an inorganic dielectric bonding layer disposed on a flexible layer. In some cases, the primary flexible hybrid bonding substrate 600 may comprise a first and second hybrid bonding surface regions 601a, 601b each comprising one or more contact pads. In some cases, the first and second hybrid bonding surface regions 601a, 601b may be formed on opposite major surfaces of the primary flexible hybrid bonding substrate 600. In some cases, the contact pads of the first hybrid bonding surface region 601a or second hybrid bonding surface region 601b may be configured for direct bonding to each other. Additionally, in some embodiments, the primary flexible hybrid bonding substrate 600 may comprise one or more hybrid bonding regions (e.g., third and fourth hybrid bonding regions 603a and 603b) configured for bonding to one or more components.

In some implementations, at the first fabrication step two primary flexible hybrid bonding substrate may be provided wherein each primary flexible hybrid bonding substrate comprises a hybrid bonding surface configured to be hybrid bonded to a hybrid bonding surface of the other. Additionally, each primary flexible hybrid bonding substrate may comprise one or more hybrid bonding regions configured for bonding to one or more components.

At fabrication step-2 (FIG. 6B) the primary flexible hybrid bonding substrate 600 is mounted on a dicing frame, coated with a protective layer, and then diced to singulate (or separate) one or both main portion 602 and a branch portion 604. In some embodiments, where two primary flexible hybrid bonding substrates are provided, the main portion 602 and the branch portion 604 may be separated from two different primary flexible hybrid bonding substrates. In various implementations, the protective layer may comprise an organic layer (e.g., a photoresist layer) spin coated or sprayed over the primary flexible hybrid bonding substrate 600 or another primary flexible hybrid bonding substrate. In some examples, the protective layer may cover at least the first and second hybrid bonding surface regions 601a, 601b. In some cases, the main portion 602 may comprise the first hybrid bonding surface 601a and the branch portion 604 may comprise the second hybrid bonding surface 601b.

At fabrication step-3 The protective layer is removed from the singulated main and branch portions 602, 604, and the singulated main and branch portions 602, 604 are cleaned to further remove unwanted singulation debris from the substrates. In some examples, the protective layer and debris may be removed using a suitable cleaner or resist developer. Next, the first and second hybrid bonding surface regions 601a, 601b, are rinsed with DI water or another suitable solvent, dried and then bonding surfaces are activated, cleaned, and prepared for hybrid (direct) bonding. In some cases, activation of the first and second hybrid bonding surface regions 601a, 601b may comprise adding suitable species (e.g., nitrogen species) to transform hybrid surface to a hybrid bonding surface.

At fabrication step-4 (FIG. 6C) the main and branch portions 602, 604, are reoriented and/or displaced to align one or more contact pads in the first hybrid bonding surface region 601a of main portion 602 to one or more contact pads in the second hybrid bonding surface region 601b of the branch portion 604 for direct bonding. In some examples, where the main and branch portions 602, 604 are separated from a single primary hybrid flexible substrate 600 and the hybrid bonding surface regions 601b, 601a are on the same major surface of the of the hybrid flexible substrate 600, the main portion 602 or the branch portion 604 may be flipped such that the hybrid bonding surface regions 601a, 601b face each other.

Next, the first and second hybrid bonding surface regions 601a, 601b are brought into contact and are hybrid bonded to form a branched flexible hybrid bonding substrate 610 comprising a main section 610a and a branch section 610b. In some examples, direct bonding may further comprise annealing the resulting hybrid bonding interface at high temperature. Depending on the thermal properties of the flexible substrates and the composition of the conductive pads in the hybrid bonding surface regions, the annealing temperature can be from 80° C. to 350° C. and in some embodiments from 120° C. to 300° C. In some cases, high temperature bonding process may be performed in an inert or vacuum ambient. The annealing time can be from 15 minutes to 6 hours or longer. In some cases, the annealing time can be inversely proportional to the annealing temperature.

In some embodiments, one or more components may be hybrid bonded to a region of a hybrid bonding surface on the same or opposite major surfaces of the resulting branched flexible hybrid bonding substrate 610 (FIG. 6E). In the example shown, a first component 606 is hybrid bonded to the third hybrid bonding region 603a of the main portion 602 and a second component 608 is hybrid bonded to the fourth hybrid bonding region 603b of the branch portion 604.

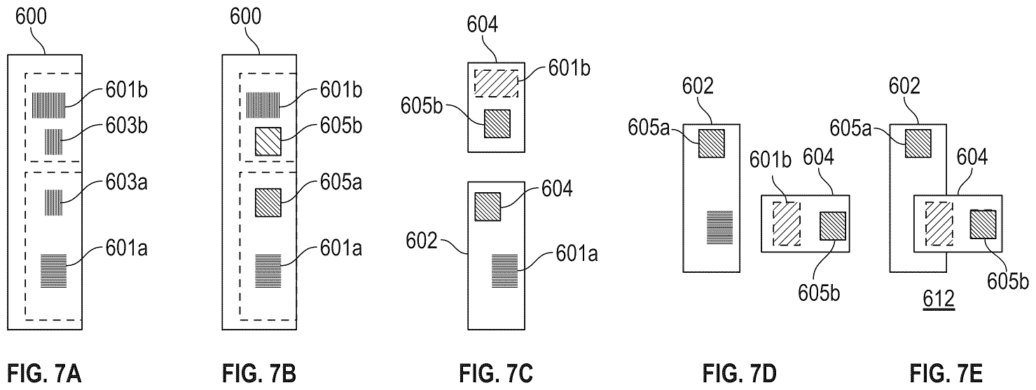

FIG. 7A to 7E schematically illustrate selected steps of an example process for fabricating a branched flexible bonded structure comprising a branched flexible hybrid bonding substrate and one or more components bonded (e.g., hybrid bonded) to each of a main section and a branch section thereof.

At a first fabrication step (FIG. 7A), at least one primary flexible hybrid bonding substrate 600 is provided. In some examples, the primary flexible hybrid bonding substrate 600 may comprise one or more features described above with respect to flexible hybrid bonding substrates 100 and 200. In some cases, the primary flexible hybrid bonding substrate 600 may comprise first and second hybrid bonding surface regions 601a, 601b each comprising one or more contact pads. In some cases, the first and second hybrid bonding surface regions 601a, 601b may be formed on opposite major surfaces of the primary flexible hybrid bonding substrate 600. In some cases, the contact pads of the first hybrid bonding surface region 601a or second hybrid bonding surface region 601b may be configured for direct bonding to each other. Additionally, in some embodiments, the primary flexible hybrid bonding substrate 600 may comprise one or more hybrid bonding regions (e.g., third and fourth hybrid bonding regions 603a, 603b) configured for bonding to one or more components.

In some implementations, at the first fabrication step, two primary flexible hybrid bonding substrate may be provided wherein each primary flexible hybrid bonding substrate comprises a hybrid bonding surface configured to be hybrid bonded to a hybrid bonding surface of the other. Additionally, each primary flexible hybrid bonding substrate may comprise one or more hybrid bonding regions configured for bonding to one or more components.

At fabrication step-2 (FIG. 7B) one or more components may be hybrid bonded to hybrid bonding regions of the primary flexible hybrid bonding substrate 600. In the example shown, a first component 605a is hybrid bonded to the third hybrid bonding region 603a, and a second component 605b is hybrid bonded to the fourth hybrid bonding region 603b. In some embodiments, where two separate hybrid bonded substrates are provided, a component may be hybrid bonded to a hybrid bonding surface of a different flexible hybrid bonding substrate. In some examples, direct bonding a component may comprise aligning and then contacting the contact pads of the first hybrid bonding region (or the second hybrid bonding region 601b) with those of a hybrid bonding region of the component and hybrid bonding the resulting interface to form a hybrid bonding region or interface. In some cases, the bond energy of the resulting hybrid bonding region/interface may be further strengthened by annealing the bonded flexible substrates at low temperature (<100° C.).

At fabrication step-3 the primary flexible hybrid bonding substrate 600, having two directly components 605a, 605b, is mounted on a dicing frame, coated with a protective layer, and then diced to separate one or both main portion 602 and a branch portion 604. In some examples, the protective layer may cover at least the first and second hybrid bonding surface regions 601a, 601b may. In some embodiments, where two separate hybrid bonded substrates are provided, the main portion 602 and the branch portion each may be separated from a different flexible hybrid bonding substrate. The main portion 602 and the branch portion 604 each may include one of the hybrid bonding surfaces 601a, 601b and a hybrid bonded component (FIG. 7C).

At fabrication step-4 the protective layer is removed and singulated main and branch portions 602, 604, are cleaned. Next the first and second hybrid bonding surface regions 601a, 601b, are activated, cleaned, and prepared for direct bonding. In some cases, activation of the first and second hybrid bonding surface regions 601a, 601b may comprise adding suitable species (e.g., nitrogen species) to transform hybrid surface to a hybrid bonding surface.

At fabrication step-5 (FIG. 7D) the main and branch portions 602, 604, are reoriented and/or displaced to align the one or more contact pads of the first hybrid bonding surface region 601a to one or more contact pads of the second hybrid bonding surface region 601b for direct bonding. In some examples, where the main and branch portions 602, 604 are separated from a single primary hybrid flexible substrate 600 and the hybrid bonding regions 601b, 601a are on the same major surface of the of the hybrid flexible substrate 600, the main portion 602 or the branch portion 604 may be flipped such that 601a the second hybrid bonding surface region 601b face each other.

Next, the first and second hybrid bonding surface regions 601a, 601b are brought into contact and hybrid bonded to form a branched flexible bonded structure 612 comprising a branched flexible hybrid bonding substrate having two hybrid bonded components. In some embodiments, one or more additional branch portions (branch portions singulated from one or more primary flexible substrate) may be hybrid bonded to another hybrid bonding region of the of the main flexible substrate (main portion) 602 or to the branched flexible substrate (branch portion) 604. In some embodiments, the main portion 602 may be singulated from a first primary substrate and the branch portion 604 and the additional branch portions may be singulated from a second and other primary substrates. In some embodiments, A bonding surface of each primary substrate may be cleaned and prepared for hybrid bonding and one or more components may be hybrid bonded at the various designated sites on the bonding surface. In some examples, the primary substrate may be annealed at a temperature (e.g., lower than 100° C. or lower than 80° C.) to strengthen the bond between the bonded components and the primary substrate. Nest, the primary substrate may be coated with a protective layer and mounted on a dicing substrate for singulating a main and/or a branch portion. After the singulation the main and/or branch portion, the protective layer may be cleaned from the singulated main and/or branch portions, the singulated main and/or branch portions are cleaned, prepared and then hybrid bonded to each other. In some examples, hybrid bonding main and/or branch portion may further comprise annealing the resulting hybrid bonded branched substrate or structure at a higher temperature to electrically interconnect the assembled structures as described above.

In various embodiments, the hybrid bonding substrates, layers, and structures, and the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

### EXAMPLE EMBODIMENTS

Various additional example embodiments of the disclosure can be described by the following examples:

### Example 1

A branched hybrid bonding substrate, the branched hybrid bonding substrate comprising:
a main portion extending from a first end to a second end in a first direction; and
a branch portion extending from a third end to a fourth end in a second direction different from the first direction, the branch portion hybrid bonded to the main portion along a hybrid bonded region;
wherein a first conductive feature at least partially embedded in the main portion is electrically connected to a second conductive feature at least partially embedded in the branch portion through the hybrid bonded region; and
wherein one or both of the main and branch portions comprise an insulating organic material.

### Example 2

The branched hybrid bonding substrate of Example 1, wherein the main portion comprises a first contact pad and the branch portion comprises a second contact pad, the second contact pad electrically contacting the first contact pad within the hybrid bonded region.

### Example 3

The branched hybrid bonding substrate of Example 1, further comprising a deformable layer extending between the hybrid bonded region and a contact pad formed on the main or the branch portion, the deformable region comprising the insulating organic material.

### Example 4

The branched hybrid bonding substrate of Example 1, wherein one or both main and branch portions comprise a hybrid bonding surface region, wherein the hybrid bonding surface region is configured to be hybrid bonded to a component.

### Example 5

The branched hybrid bonding substrate of Example 4, wherein the hybrid bonding surface region comprises a contact pad electrically connected to the first or second conductive feature.

### Example 6

The branched hybrid bonding substrate of Example 1, wherein the main portion includes a flexible layer comprising the insulating organic material.

### Example 7

The branched hybrid bonding substrate of Example 5, wherein the branch portion comprise the hybrid bonding surface region and includes a flexible layer comprising the insulating organic material.

### Example 8

The branched hybrid bonding substrate of any of Examples 6 and 7, wherein the flexible layer comprises a deformable region.

### Example 9

The branched hybrid bonding substrate of Example 8, wherein a Young's modulus of the deformable region is from 0.2 GPa to 45 GPa.

### Example 10

The branched hybrid bonding substrate of Example 8, wherein coefficient of thermal expansion (CTE) of the deformable region is from 3 ppm/° C. to 50 ppm/° C.

### Example 11

The branched hybrid bonding substrate of Example 8, wherein the deformable region is configured to allow the hybrid bonding surface region to be displaced with respect to the hybrid bonded region by an amount larger than 0.02% of a distance between the hybrid bonding surface region and the hybrid bonded region, without disrupting an electrical connection between the first and second conductive features.

### Example 12

The branched hybrid bonding substrate of any one of the Examples above, wherein the insulating organic material comprises a polymer.

### Example 13

The branched hybrid bonding substrate of Example 1, wherein the hybrid bonded region is formed between a first hybrid bonding surface region of the main portion and a second hybrid bonding surface region of the branch portion.

### Example 14

The branched hybrid bonding substrate of Example 13, wherein the first hybrid bonding surface region is formed on a top major surface of the main portion and the second hybrid bonding surface region is formed on a bottom major surface of the branch portion.

### Example 15

The branched hybrid bonding substrate of Example 1, wherein the first direction is substantially perpendicular to the second direction.

### Example 16

The branched hybrid bonding substrate of Example 1, wherein one or both main and branch portions comprise a hybrid bonding surface region configured to hybrid bond one or both main and branch portions to another substrate.

### Example 17

A branched hybrid bonding structure comprising:
the branched hybrid bonding substrate of Example 3; and
a component hybrid bonded to the contact pad.

### Example 18

A second branched hybrid bonding substrate comprising the branched hybrid bonding substrate of Example 17, the second branched hybrid bonding substrate comprising a hybrid bonding substrate hybrid bonded to the main portion or the branch portion.

### Example Embodiment II

### Example 1

An electronic device comprising:
a branched flexible hybrid bonding substrate comprising:
a main portion extending from a first end to a second end in a first direction; and
a branch portion extending from a third end to a fourth end in a second direction different from the first direction, the branch portion hybrid bonded to the main portion via a first hybrid bonding interface closer to the third end compared to the fourth end, the first hybrid bonding interface comprising a first conductive interface between a first contact pad formed in the main portion and a second contact pad formed in the branch portion; and
a first component hybrid bonded to the branch portion via a second hybrid bonding interface closer to the fourth end compared to the third end, the second hybrid bonding interface comprising a second conductive interface between a third contact pad formed in the branch portion and a fourth contact pad formed in a layer of the first component;
wherein the second contact pad is electrically connected to the third contact pad via a conductive line at least partially embedded in the branch portion.

### Example 2

The electronic device of Example 1, wherein one or both main and branch portions comprise a hybrid bonding surface separate from the first and second hybrid bonding interfaces, wherein the hybrid bonding surface is hybrid bonded to a second component.

### Example 3

The electronic device of Example 1, wherein at least the main branch portion comprises a hybrid bonding surface separate from the first and second hybrid bonding interfaces, wherein the hybrid bonding surface is hybrid bonded to a second component.

### Example 4

The electronic device of any one of Examples 2 and 3, wherein the hybrid bonding surface comprises a third contact pad electrically connected to the first contact pad via a transmission line at least partially embedded in the main portion.

### Example 5

The electronic device of any one of Examples 2 and 3, wherein a second component is hybrid bonded to the hybrid bonding surface.

### Example 6

The electronic device of Example 3, wherein the first component comprises a multilayer stack.

### Example 7

The electronic device of Example 6, wherein the multilayer stack comprises a memory chip, a buffer circuit, or a control circuit.

### Example 8

The electronic device of Example 7, wherein the second component comprises an inductor, an electronic processor, or an integrated voltage regulator.

### Example 9

The electronic device of Example 1, wherein the second hybrid bonding interface is formed between a top surface of the first component and the branch portion.

### Example 10

The electronic device of Example 1, wherein the first component comprises a plurality of layers vertically extending from a bottom layer to a top layer and the second hybrid bonding interface is formed between a layer of the plurality of layers below the top layer and above the bottom layer.

### Example 11

The electronic device of Example 1, wherein the second hybrid bonding interface is separated from the first hybrid bonding interface in a vertical direction perpendicular to a main surface of the main portion.

### Example 12

The electronic device of Example 1, wherein the first component is hybrid bonded to the branch portion further via a third hybrid bonding interface closer to the fourth end, the third hybrid bonding interface.

### Example 13

The electronic device of Example 1, wherein a vertical distance between the first and second hybrid bonding interfaces is equal or larger than a thickness of the main portion along a vertical direction perpendicular to a main surface of the main portion.

### Example 14

The electronic device of Example 1, wherein the main portion comprises a flexible hybrid layer.

### Example 15

The electronic device of Example 1, wherein the branch portion comprises a flexible hybrid layer.

### Example 16

The electronic device of Example 1, wherein one or both of main and branch portions comprise a flexible hybrid layer having a deformable region.

### Example 17

The electronic device of Example 16, wherein the deformable region comprises an insulating organic material.

### Example 18

The electronic device of Example 17, wherein the insulating organic material comprises a polymer.

### Example 19

The electronic device of Example 16, wherein Young's modulus of the deformable region is from 0.2 GPa to 45 GPa

### Example 20

The electronic device of Example 16, wherein coefficient of thermal expansion (CTE) of the deformable region is from 3 ppm/° C. to 50 ppm/° C.

### Example 21

The electronic device of Example 1, wherein the deformable is extended between the third and fourth ends with the branch portion.

### Example 22

The electronic device of Example 21, wherein the deformable region is configured to allow the second hybrid bonding interface to be displaced with respect to the first hybrid bonding interface by an amount larger than 0.02% of a distance between the first and the second hybrid bonding interfaces without disrupting an electrical connection between the first and second conductive interfaces therein

### Example 23

The electronic device of Example 1, wherein the first hybrid bonding surface is formed on a top major surface of the main portion and the second hybrid bonding surface is formed on a bottom major surface of the branch portion.

### Example 24

The electronic device of Example 1, wherein one or both main and branch portions comprise a component bonded to the respective portion.

### Example 25

The electronic device of Example 1, wherein the first direction is substantially perpendicular to the second direction.

### Example 26

The electronic device of Example 1, wherein one or both main and branch portions comprise a hybrid bonding surface configured to hybrid bond one or both main and branch portions to another substrate.

### Example 27

The electronic device of Example 26, wherein the hybrid bonding surface is electrically connected to the conductive line.

### Example Embodiment III

### Example 1

A method of fabricating a hybrid bonding substrate, the method comprising:
providing a master substrate;
separating a main substrate from the master substrate, the main substrate comprising a first hybrid bonding surface;
providing a branch substrate comprising a second hybrid bonding surface;
positioning the main substrate with respect to the branch substrate to align a first conductive region of the first hybrid bonding surface to a second conductive region of the second hybrid bonding surface; and
forming a first hybrid bonding interface between the main substrate and the branch substrate to electrically connect the first and second conductive regions.

### Example 2

The method of Example 1, wherein providing the branch substrate comprises separating the branch substrate from the master substrate.

### Example 3

The method of Example 1, wherein providing the branch substrate comprised separating the branch substrate from a second master substrate.

### Example 4

The method of Example 1, wherein the first hybrid bonding surface comprises a third conductive region configured for direct bonding to a component, a layer, or another substrate, the fourth conductive region electrically connected to the first conductive region via a conductive line at least partially embedded in the main substrate.

### Example 5

The method of Example 4, wherein the second hybrid bonding surface comprises a fourth conductive region configured for direct bonding to a component, a layer, or another substrate, the fourth conductive region electrically connected to the second conductive region via a conductive line at least partially embedded in the branch substrate.

### Example 6

A method of fabricating an electronic device, the method comprising fabricating a hybrid bonding substrate using the method of Example 5 and directly bonding a first component to the branch substrate, wherein the first component is electrically connected to the fourth conductive region.

### Example 7

The method of Example 6, further comprising bonding a second component to the main substrate, wherein the second component is electrically connected to the third conductive region.

### Example 8

The method of Example 1, wherein one or both of the main substrate and the branch substrate comprises a deformable region.

### Example 9

The method of Example 8, wherein the deformable region comprises an insulating organic material.

### Example 10

The method of Example 9, wherein the insulating organic material comprises a polymer.

### Example 11

The method of Example 8, wherein Young's modulus of the deformable region is from 0.2 GPa to 45 GPa.

### Example 12

The method of Example 8, wherein coefficient of thermal expansion (CTE) of the deformable region is from 3 ppm/° C. to 50 ppm/° C.

### Example 13

The method of Example 8, wherein the deformable region is configured to allow a second hybrid bonding interface of the main substrate or the branch substrate to be displaced with respect to the first hybrid bonding interface by an amount larger than 0.02% of a distance between the first and the second hybrid bonding interfaces without disrupting an electrical connection between the conductive regions of the first hybrid bonding interface and that of the second hybrid bonding interface.

### Example Embodiment IV

### Example 1

A method of fabricating a flexible hybrid structure, the method comprising:
providing a master substrate comprising a main portion, the main portion comprising a first hybrid bonding surface;
bonding a first component to the main portion to form a main structure;
separating the main structure from the master substrate, the main substrate comprising the main portion;
providing a branch structure comprising a branch substrate having and a second component bonded thereon, the branch substrate comprising a second hybrid bonding surface;
positioning the main structure with respect to the branch structure to align a first conductive region of the first hybrid bonding surface to a second conductive region of the second hybrid bonding surface; and
hybrid bonding the main substrate to the branch substrate to forming a hybrid bonding interface therebetween, the hybrid bonding interface electrically connecting the first and second conductive regions;
wherein one or both main structure and the branch structure comprise a deformable region.

### Example 2

The method of Example 1, wherein providing the branch structure comprises separating the branch substrate from the master substrate.

### Example 3

The method of Example 1, wherein providing the branch structure comprised separating the branch substrate from a second master substrate and directly bonding the second component to the branch substrate.

### Example 4

The method of Example 1, wherein the first component is electrically connected to the first conductive region via a conductive line at least partially embedded in the main substrate.

### Example 5

The method of Example 1, wherein the second component is electrically connected to the second conductive region via a conductive line at least partially embedded in the branch substrate.

### Example 6

The method of Example 1, wherein Young's modulus of the deformable region is from 0.2 GPa to 45 GPa.

### Example 7

The method of Example 1, wherein coefficient of thermal expansion (CTE) of the deformable region is from 3 ppm/° C. to 50 ppm/° C.

### Example 8

The method of Example 1, wherein the first component is electrically connected to the second component the hybrid bonding interface.

### Example 9

The method of Example 8, wherein the deformable region is configured to allow the first component to be displaced with respect to the second component by an amount larger than 0.02% of a distance between the first and the second components without disrupting the electrical connection between the first and the second components.

### Terminology

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A branched hybrid bonding substrate, the branched hybrid bonding substrate comprising:
a main portion extending from a first end to a second end in a first direction; and
a branch portion extending from a third end to a fourth end in a second direction different from the first direction, the branch portion hybrid bonded to the main portion along a hybrid bonded region;
wherein a first conductive feature at least partially embedded in the main portion is electrically connected to a second conductive feature at least partially embedded in the branch portion through the hybrid bonded region; and
wherein one or both of the main and branch portions comprise an insulating organic material.

2. The branched hybrid bonding substrate of claim 1, wherein the main portion comprises a first contact pad and the branch portion comprises a second contact pad, the second contact pad electrically contacting the first contact pad within the hybrid bonded region.

3. The branched hybrid bonding substrate of claim 1, further comprising a deformable region extending between the hybrid bonded region and a contact pad formed on the main portion or the branch portion, the deformable region comprising the insulating organic material.

4. The branched hybrid bonding substrate of claim 1, wherein one or both main and branch portions comprise a hybrid bonding surface region, wherein the hybrid bonding surface region is configured to be hybrid bonded to a component.

5. The branched hybrid bonding substrate of claim 4, wherein the hybrid bonding surface region comprises a contact pad electrically connected to the first or second conductive feature.

6. The branched hybrid bonding substrate of claim 1, wherein the main portion includes a flexible layer comprising the insulating organic material.

7. The branched hybrid bonding substrate of claim 5, wherein the branch portion comprises the hybrid bonding surface region and includes a flexible layer comprising the insulating organic material.

8. The branched hybrid bonding substrate of claim 7, wherein the flexible layer comprises a deformable region.

9. The branched hybrid bonding substrate of claim 8, wherein a Young's modulus of the deformable region is from 0.2 GPa to 45 GPa.

10. The branched hybrid bonding substrate of claim 8, wherein coefficient of thermal expansion (CTE) of the deformable region is from 3 ppm/° C. to 50 ppm/° C.

11. The branched hybrid bonding substrate of claim 8, wherein the deformable region is configured to allow the hybrid bonding surface region to be displaced with respect to the hybrid bonded region by an amount larger than 0.02% of a distance between the hybrid bonding surface region and the hybrid bonded region, without disrupting an electrical connection between the first and second conductive features.

12. The branched hybrid bonding substrate of claim 1, wherein the insulating organic material comprises a polymer.

13. The branched hybrid bonding substrate of claim 1, wherein the hybrid bonded region is formed between a first hybrid bonding surface region of the main portion and a second hybrid bonding surface region of the branch portion.

14. The branched hybrid bonding substrate of claim 13, wherein the first hybrid bonding surface region is formed on a top major surface of the main portion and the second hybrid bonding surface region is formed on a bottom major surface of the branch portion.

15. The branched hybrid bonding substrate of claim 1, wherein the first direction is substantially perpendicular to the second direction.

16. The branched hybrid bonding substrate of claim 1, wherein one or both main and branch portions comprise a hybrid bonding surface region configured to hybrid bond one or both main and branch portions to another substrate.

17. A branched hybrid bonding structure comprising:
the branched hybrid bonding substrate of claim 3; and
a component hybrid bonded to the contact pad.

18. A second branched hybrid bonding substrate comprising the branched hybrid bonding substrate of claim 17, the second branched hybrid bonding substrate comprising a hybrid bonding substrate hybrid bonded to the main portion or the branch portion.
